(19) United States
(12) Patent Application Publication
(10) Pub. No.: US 2025/0081414 A1
(43) Pub. Date: Mar. 6, 2025

(54) RECTIFYING-ELEMENT-MODULE COOLING UNIT

(71) Applicant: SANSHA ELECTRIC MANUFACTURING CO., LTD., Osaka (JP)

(72) Inventors: Shozo HATTORI, Osaka (JP); Kazuki TODA, Osaka (JP); Yuya NAKATSUKA, Osaka (JP); Yoshiki SEMBON, Osaka (JP)

(73) Assignee: SANSHA ELECTRIC MANUFACTURING CO., LTD., Osaka (JP)

(21) Appl. No.: 18/823,925

(22) Filed: Sep. 4, 2024

(30) Foreign Application Priority Data
Sep. 4, 2023 (JP) 2023-143236
Sep. 4, 2023 (JP) 2023-143237

(51) Int. Cl. H05K 7/20; H02M 7/00

(52) U.S. Cl. CPC H05K 7/209; H02M 7/003

(57) ABSTRACT

A rectifying-element-module cooling unit is provided. The unit includes a rectifying element module, a substrate, a first conductive cooling part, a second conductive cooling part, and a conductive cooling promoting part electrically connected to one of the first conductive cooling part and the second conductive cooling part and insulatively connected to the other one thereof. Part of a first current path is configured of a first penetrating current path penetrating through the substrate from a substrate front surface to a substrate back surface, and part of a second current path is configured of a second penetrating current path penetrating through the substrate from the substrate front surface to the substrate back surface.

### FIELD OF THE INVENTION

The present invention relates to a rectifying-element-module cooling unit.

### DESCRIPTION OF THE BACKGROUND OF ART

A power conversion device includes, for example, a primary-side circuit for receiving input voltage, a secondary-side circuit for outputting output voltage, and a transformer magnetically connecting the primary-side circuit and the secondary-side circuit. The secondary-side circuit is provided with a rectifier circuit for rectifying a voltage waveform occurring at a secondary-side winding of the transformer. In this rectifier circuit, a large current flows to cause heat. Since heat causes, for example, destruction of an element configuring the rectifier circuit, it is required to cool the rectifier circuit.

Japanese Patent Application Publication No. 2016/144238 discloses a power conversion device including a transformer, a rectifying element configuring a rectifier circuit on a secondary side of the transformer, a choke coil configuring a smoothing circuit on the secondary side of the transformer, and a housing having the choke coil installed therein and also having a cooling part. The housing has a water path as the cooling part formed in a lower portion thereof, and has a pair of standing parts that stand with respect to the water path. In a state in which the choke coil is interposed inside the pair of standing parts, a metal substrate is arranged along an outer surface of each standing part. On each of these metal substrates, the rectifier element is arranged. With heat on the rectifying element and the metal substrate dissipated via each standing part to the water path, the rectifying elements and the metal substrates can be cooled.

### SUMMARY OF THE INVENTION

However, in the structure of Japanese Patent Application Publication No. 2016/144238, while heat of the rectifying elements and the metal substrates can be dissipated, heat on the metal substrates itself cannot be suppressed. That is, since a large current flowing through the rectifying elements is extracted to the outside via the metal substrates, the large current flows through the metal substrates. Thus, heat of the metal substrates is large, and there is a possibility that heat of the metal substrates may cause destruction of the rectifying elements and so forth. Thus, it is desired to improve a cooling structure of the rectifier circuit.

Thus, a main object of the present invention is to provide a rectifying-element-module cooling unit.

A rectifying-element-module cooling unit according to the present invention includes a rectifying element module having an element body in which a rectifying element having a first element terminal and a second element terminal is arranged, a first module terminal electrically connected to the first element terminal, and a second module terminal electrically connected to the second element terminal, a substrate formed in a plate shape, having a substrate front surface and a substrate back surface, and having the rectifying element module arranged on the substrate front surface side; a first conductive cooling part for electrically connecting a first external member arranged outside the rectifying-element-module cooling unit and the first module terminal together and mainly cooling heat generated by a first current passing through the first element terminal; a second conductive cooling part for electrically connecting a second external member arranged outside the rectifying-element-module cooling unit and the second module terminal together and mainly cooling heat generated by a second current passing through the second element terminal, and a conductive cooling promoting part for cooling the first conductive cooling part and the second conductive cooling part, the conductive cooling promoting part having an arrangement surface where the first conductive cooling part and the second conductive cooling part are arranged, the cooling promoting part being electrically connected to one of the first conductive cooling part and the second conductive cooling part via the arrangement surface and insulatively connected to the other thereof, wherein part of a first current path of the first current from the first element terminal via the first module terminal and the first conductive cooling part to the first external member is configured of a first penetrating current path penetrating through the substrate from the substrate front surface to the substrate back surface.

According to the above-described structure, it is possible to provide a rectifying-element-module cooling unit for cooling a substrate and a rectifying element.

According to the present invention, it is possible to provide a rectifying-element-module cooling unit.

The above-described object and other objects, characteristics, and advantages will become more apparent from description for carrying out the invention below with reference to the drawings.

### BRIEF DESCRIPTION OF THE DRAWINGS

FIG. 1 is a side view of a rectifying-element-module cooling unit according to a first embodiment of the present invention;

FIG. 2 is an upper view of the rectifying-element-module cooling unit according to the first embodiment of the present invention;

FIG. 3 is a circuit diagram of a power conversion device having a synchronous rectifier circuit;

FIG. 4A is an upper perspective view of a rectifying element module;

FIG. 4B is a back perspective view of FIG. 4A;

FIG. 5 is a current path diagram depicting a current flow in the rectifying-element-module cooling unit in FIG. 1;

FIG. 6A is a side view of a rectifying-element-module cooling unit of another mode 1 according to the first embodiment of the present invention;

FIG. 6B is a side view of a rectifying-element-module cooling unit of another mode 2 according to the first embodiment of the present invention;

FIG. 7 is a side view of a rectifying-element-module cooling unit according to a second embodiment of the present invention;

FIG. 8 is an upper view of the rectifying-element-module cooling unit according to the second embodiment of the present invention;

FIG. 9A is an upper perspective view of a rectifying element module;

FIG. 9B is a back perspective view of FIG. 9A;

FIG. 10 is a current path diagram depicting a current flow in the rectifying-element-module cooling unit in FIG. 7;

FIG. 11A is a side view of a rectifying-element-module cooling unit of another mode 1 according to the second embodiment of the present invention;

FIG. 11B is a side view of a rectifying-element-module cooling unit of another mode 2 according to the second embodiment of the present invention;

FIG. 11C is a side view of a rectifying-element-module cooling unit of another mode 3 according to the second embodiment of the present invention;

FIG. 12 is a circuit diagram of a power conversion device having a synchronous rectifier circuit with another structure 1;

FIG. 13 is a circuit diagram of a power conversion device having a synchronous rectifier circuit with another structure 2;

FIG. 14 is a circuit diagram of a power conversion device having a synchronous rectifier circuit with another structure 3;

FIG. 15 is a circuit diagram of a power conversion device having a synchronous rectifier circuit with another structure 4; and

FIG. 16 is a circuit diagram of a power conversion device having a rectifier circuit.

### DETAILED DESCRIPTION OF THE INVENTION

### 1. First Embodiment

### (1) Structure of Rectifying-Element-Module Cooling Unit

The structure of a rectifying-element-module cooling unit 100 according to a first embodiment of the present invention is described with reference to the drawings.

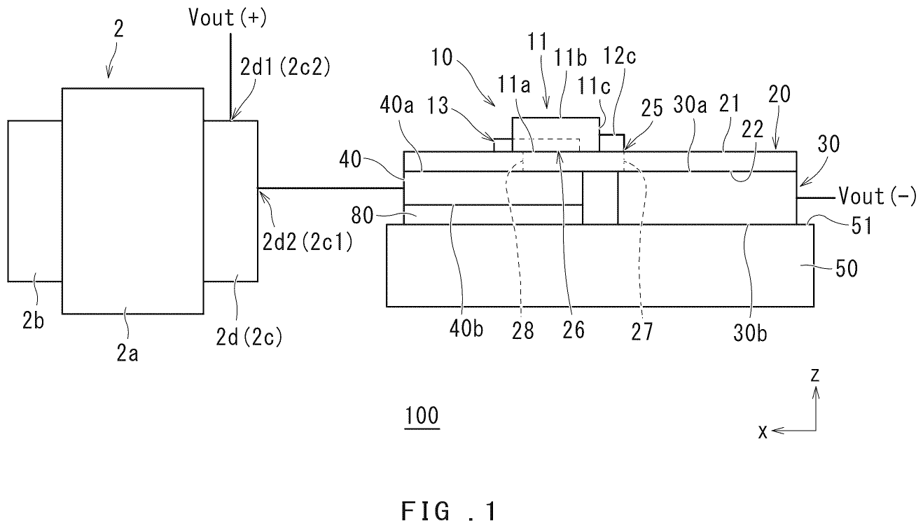

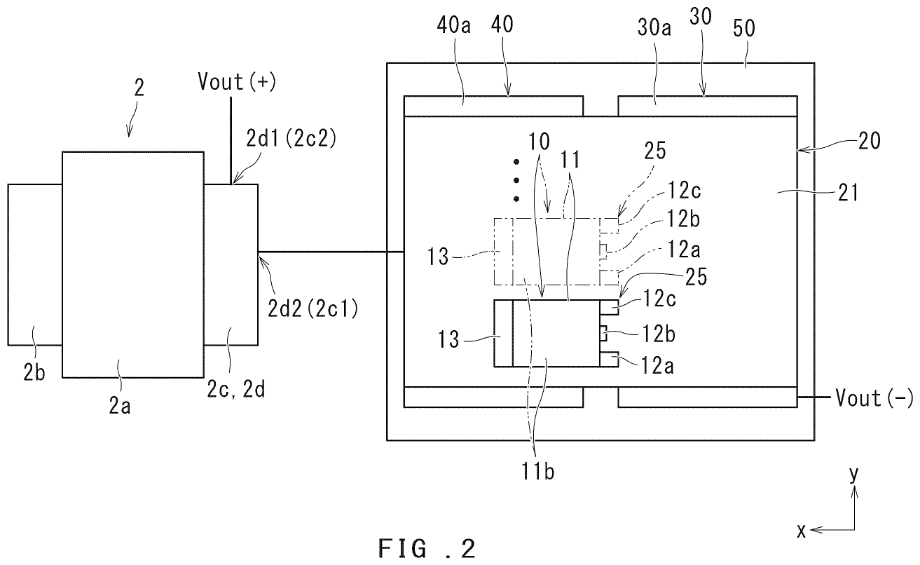

FIG. 1 is a side view of the rectifier-element-module cooling unit according to the first embodiment of the present invention. FIG. 2 is an upper view of the rectifying-element-module cooling unit according to the first embodiment of the present invention.

The rectifying-element-module cooling unit 100 includes a rectifying element module 10, a substrate 20, a first conductive cooling part 30, a second conductive cooling part 40, and a cooling promoting part 50. The rectifying element module 10 generates rectified output voltage. On the substrate 20, the rectifying element module 10 is arranged. The first and second conductive cooling parts 30 and 40 each electrically transmit a signal in the rectifying element module 10 and cool the rectifying element module 10 and the substrate 20. In FIG. 1, FIG. 2 and others, a direction in which the first and second conductive cooling parts 30 and 40 are aligned is taken as an x direction. A direction orthogonal to the x direction is taken as a y direction. A direction orthogonal to the x direction and the y direction is taken as a z direction, and may also be referred to as a vertical direction, or above/below. Furthermore, a plane parallel to an x-y plane is referred to as a horizontal plane, and a direction along the horizontal plane may be referred to as a horizontal direction. In the present embodiment, the substrate 20 extends in the horizontal direction. Also, a plane perpendicular to the x-y plane may be referred to as a vertical plane. In the following, each component is described.

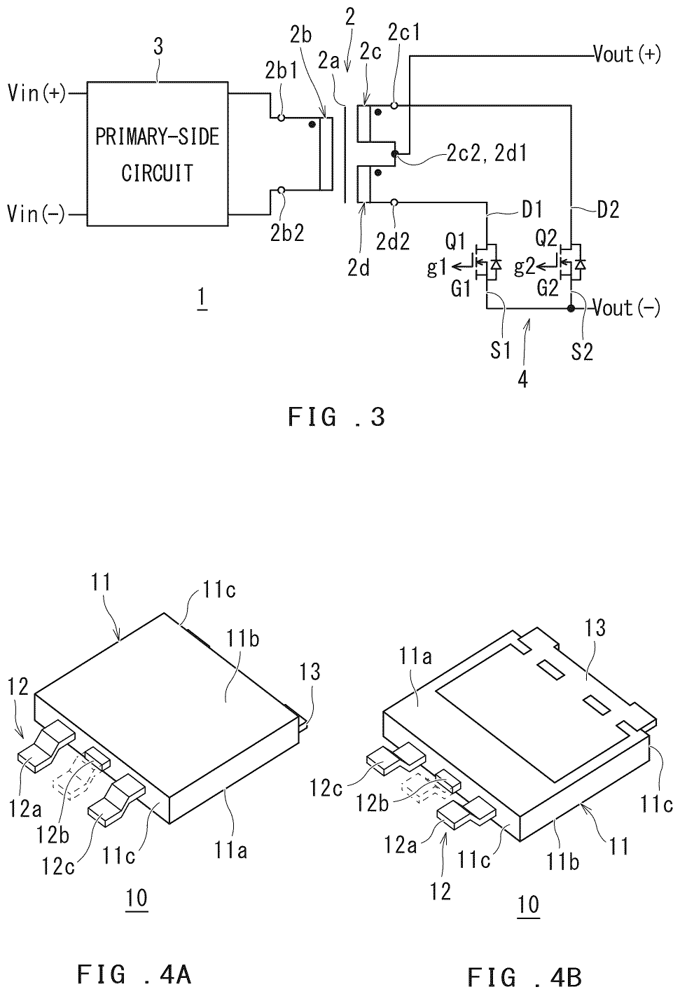

The rectifying element module 10 has therein a rectifying element for generating rectified output voltage. The rectifying element configures a synchronous rectifier circuit. The synchronous rectifier circuit as described above is used in a power conversion device 1. FIG. 3 is a circuitry view of a power conversion device having a synchronous rectifier circuit.

Among a variety of power conversion devices using synchronous rectifier circuits, the power conversion device 1 described herein is of a center-tapped type, by way of example. As depicted in FIG. 3, the power conversion device 1 includes a transformer 2, a primary-side circuit 3, and a secondary-side circuit 4. The primary-side circuit 3 generates alternating voltage from direct voltage, and supplies the alternating voltage to a primary-side winding 2b of the transformer 2. Current flowing through the primary-side winding 2b generates a magnetic field, and electromagnetic induction of the magnetic field induces current to a secondary-side winding 2c-2d of the transformer 2 (in the present embodiment, one example of a second external member). With this, output voltage in accordance with the turns ratio is obtained from the secondary-side winding 2c-2d.

The transformer 2 has a core 2a, the primary-side winding 2b, and the secondary-side winding 2c-2d. The primary-side winding 2b is wound around the core 2a from a primary-side winding start end 2b1 toward a primary-side winding finish end 2b2. The secondary-side winding 2c-2d, including a first part winding 2c and a second part winding 2d, are wound around the core 2a respectively. The first part winding 2c is wound around the core 2a from a first part winding start end 2cl toward a first part winding finish end 2c2. The second part winding 2d is wound around the core 2a from a second part winding start end 2d1 toward a second part winding finish end 2d2. Also, the first part winding finish end 2c2 and the second part winding start end 2d1 are connected together so that the first part winding 2c and the second part winding 2d are in series. The first part winding start end 2cl and the second part winding finish end 2d2 are connected to a secondary-side output (−) line Vout (−) (in the present embodiment, one example of a first external member) via the secondary-side circuit 4. A connecting portion between the first part winding finish end 2c2 and the second part winding start end 2d1 is connected to a secondary-side output (+) line Vout (+). From the secondary-side output (+) line Vout (+), output voltage induced in the first part winding 2c and the second part winding 2d is outputted.

The primary-side circuit 3 can be any component capable of receiving inputs of direct voltage from the primary-side input (+) line Vin (+) and the primary-side input (−) line Vin (−) to generate alternating voltage from the direct voltage. For example, the primary-side circuit 3 has a plurality of transistors or the like that receive direct voltage from the primary-side input (+) line Vin (+) and the primary-side input (−) line Vin (−). By switching the plurality of transistors, the primary-side circuit 3 can generate alternating voltage from direct voltage.

The secondary-side circuit 4 rectifies the output voltage inducted in the secondary-side winding 2c-2d. The secondary-side circuit 4 has first and second transistors Q1 and Q2 (one example of a rectifying element). The first transistor Q1 has a first gate terminal G1, a first source terminal S1 (one example of a first element terminal), and a first drain terminal D1 (one example of a second element terminal). The second transistor Q2 has a second gate terminal G2, a second source terminal S2 (one example of the first element terminal), and a second drain terminal D2 (one example of the second element terminal). To the first gate terminal G1, a first gate signal g1 is inputted. To the second gate terminal G2, a second gate signal g2 is inputted. Also, the first and second drain terminals D1 and D2 are connected to the secondary-side winding 2d-2c, respectively (in the present embodiment, one example of the second external member). Specifically, the first drain terminal D1 is connected to the second part winding finish end 2d2, and the second drain terminal D2 is connected to the first part winding start end 2cl. The first and second source terminals S1 and S2 are both connected to the secondary-side output (−) line Vout (−).

In the secondary-side circuit 4 as described above, the first and second transistors Q1 and Q2 switchably operate based on the difference in voltage applied to the first and second gate terminals G1 and G2, the first and second source terminals S1 and S2, and the first and second drain terminals D1 and D2. In the example of FIG. 3, the first and second transistors Q1 and Q2 are alternately turned ON and OFF. With this, the output voltage from the first part winding 2c and the output voltage from the second part winding 2d are alternately outputted from the secondary-side output (+) line Vout (+) and, as a result, rectified output voltage is outputted from the secondary-side output (+) line Vout (+). In the present embodiment, the first and second transistors Q1 and Q2 configure a synchronous rectifier circuit.

Also, the secondary-side circuit 4 may include, in addition to the synchronous rectifier circuit (one example of a rectifier circuit), a circuit related to rectification, such as a smoothing circuit.

In the present embodiment, the transistors are, for example, MOSFET transistors (metal oxide semiconductor field effect transistors). However, in place of MOSFET transistors, IGBTs (insulated gate bipolar transistors) or the like can be used.

Furthermore, in the present embodiment, the transistors are preferably power transistors, and those supporting a high current at least equal to or larger than 500 A are preferable.

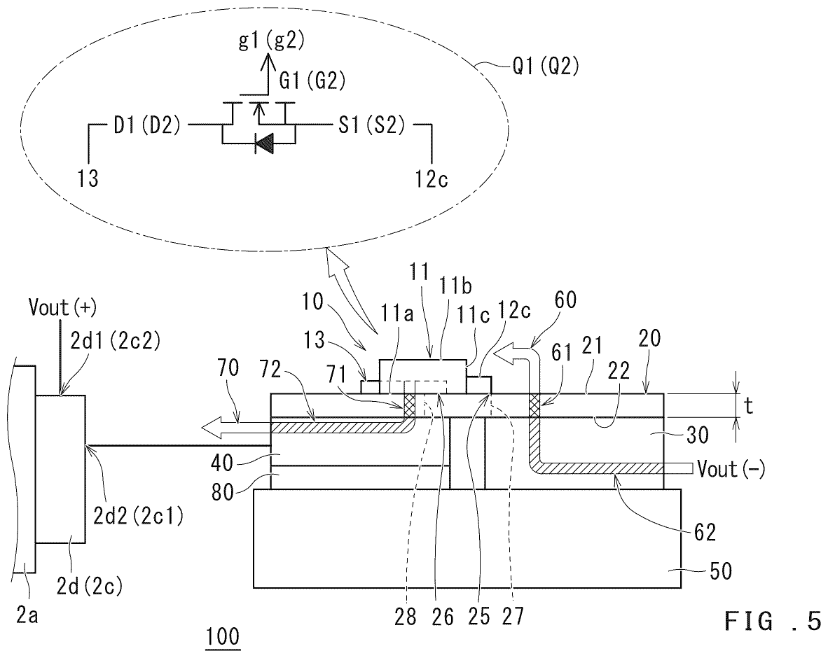

Next, the rectifying element module 10 having the first and second transistors Q1 and Q2 (one example of the rectifying element) is described. FIG. 4A is an upper perspective view of the rectifying element module, and FIG. 4B is a back perspective view of FIG. 4A.

As depicted in FIGS. 4A and 4B, the rectifying element module 10 has an element body 11, first lead terminals 12, and a second module terminal 13. Inside the element body 11, a transistor (first transistor Q1 or second transistor Q2) is arranged. With the transistor sealed with resin, the element body 11 is configured. The element body 11 has an element-body back surface 11a, an element-body front surface 11b, and element-body side surfaces 11c. In the present embodiment, the element body 11 has a substantially rectangular parallelepiped shape. The element-body back surface 11a is the back surface of the element body 11. The element-body front surface 11b is the front surface of the element body 11 opposed to the element-body back surface 11a. The element-body side surfaces 11c are side surfaces of the element body 11, which are surfaces of the element body 11 other than the element-body back surface 11a and the element-body front surface 11b.

In the following, the rectifying element module 10 is described on the assumption that the first transistor Q1 is arranged inside the element body 11.

In the present embodiment, the first lead terminals 12 extend from the element body 11. The first lead terminals 12 are formed of a conductive material, for example, a metal having copper as a main component. The first lead terminals 12 include, for example, a gate pin 12a, an unused pin 12b, and a first module terminal 12c. The gate pin 12a, the unused pin 12b and the first module terminal 12c are aligned in sequence in a direction along the element-body back surface 11a. The unused pin 12b is cut and is not used. The first module terminal 12c is electrically connected to the first source terminal S1. The gate pin 12a is electrically connected to the first gate terminal G1. The gate pin 12a and the first module terminal 12c extend from one of the element-body side surfaces 11c to the outside of the element body 11 and also extend toward the element-body back surface 11a. Although this is not meant to be restrictive, in the present embodiment, the gate pin 12a and the first module terminal 12c each have a portion extending from the element-body side surface 11c along the element-body back surface 11a and a portion warped or curved from a tip of the above-described portion and then extending toward the element-body back surface 11a. Also, the one element-body side surface 11c from which the gate pin 12a and the first module terminal 12c extend is a surface opposed to a side where part of the second module terminal 13 protrudes from the element body 11. That is, the direction in which the first lead terminals 12 extend from the element body 11 and the direction in which the second module terminal 13 protrudes from the element body 11 are opposed to each other. Note that in FIG. 1 and others, for convenience of description, only the first module terminal 12c among the first lead terminals 12 is depicted.

The second module terminal 13 is electrically connected to the first drain terminal D1. The second module terminal 13 is arranged at least partially in contact with the element-body back surface 11a. In the present embodiment, the second module terminal 13 has a plate shape extending along the element-body back surface 11a, and is arranged partially in surface contact with the element-body back surface 11a. The second module terminal 13 is arranged so as to be flush with the element-body back surface 11a. Also, the second module terminal 13 has the remaining portion not in contact with the element-body back surface 11a extending from one element-body side surface 11c along the element-body back surface 11a to the outside of the element body 11 in a direction opposite to a direction in which the first module terminal 12c extends from the element body 11. The second module terminal 13 as described above is formed of a conductive material, for example, a metal having copper as a main component.

In the above-described rectifying element module 10, the first module terminal 12c extends to the outside of the element body 11 and also extends toward the element-body back surface 11a, and the second module terminal 13 is arranged at least partially in contact with the element-body back surface 11a. The above-described rectifying element module 10 is, for example, a surface mount component in the above-described state as a standard state. Thus, since the rectifying element module 10 in the standard state can be attached to the substrate 20, normal attachment is only required, and no additional work is required.

As depicted in FIG. 1 and FIG. 2, the substrate 20 is for arranging the rectifying element module 10. The substrate 20 is formed in a plate shape, and has the substrate front surface 21 and the substrate back surface 22. The substrate 20 is arranged along an arrangement surface 51 of the cooling promoting part 50. Here, the substrate 20 is arranged in the horizontal direction, and the substrate front surface 21 and the substrate back surface 22 are horizontal planes. The rectifying element module 10 is arranged on the substrate front surface 21 of the substrate 20. The first module terminal 12c extends from the element-body side surface 11c of the element body 11 along the element-body back surface 11a, and has a tip extending toward the element-body back surface 11a attached to the substrate 20 at a first attachment portion 25. In the present embodiment, the first module terminal 12c extends from the element-body side surface 11c in the x direction and downward in the z direction, and is attached to the first substrate 20 at the first attachment portion 25. Furthermore, the first module terminal 12c is electrically connected to the first conductive cooling part 30 via a first penetrating member 27. The first penetrating member 27 is formed of a conductive member penetrating through the substrate 20 in a thickness direction (z direction) from the substrate front surface 21 to the substrate back surface 22. The first penetrating member 27 is provided so as to correspond to the first attachment portion 25, and electrically connects the first module terminal 12c attached to the first attachment portion 25 and the first conductive cooling part 30. Also, although omitted in FIG. 1, as with the first module terminal 12c, the gate pin 12a extends along the element-body back surface 11a and has a tip extending toward the element-body back surface 11a attached to the substrate 20. For example, the gate pin 12a is electrically connected to a gate signal circuit, which is not depicted, via a wire (not depicted) on the substrate 20, to receive a supply of the first gate signal g1.

The element body 11 and the second module terminal 13 are in contact with each other in a state of being along the substrate front surface 21. Specifically, the first module terminal 12c extends along the element-body back surface 11a and, in a state of extending toward the element-body back surface 11a, is attached to the substrate front surface 21. On the other hand, the element body 11 and the second module terminal 13 are attached to the substrate front surface 21 in contact with the substrate front surface 21. A portion where the second module terminal 13 is attached in contact with the substrate front surface 21 is hereinafter referred to as a second attachment portion 26. Furthermore, the second module terminal 13 is electrically connected to the second conductive cooling part 40 via a second penetrating member 28. The second penetrating member 28 is formed of a conductive member penetrating through the substrate 20 in the thickness direction (z direction) from the substrate front surface 21 to the substrate back surface 22. The second penetrating member 28 is provided so as to correspond to the second attachment portion 26, and electrically connects the second module terminal 13 attached to the second attachment portion 26 and the second conductive cooling part 40.

In the substrate 20, at least one penetration hole (not depicted) is provided, through which the first and second penetrating members 27 and 28 can penetrate from the substrate front surface 21 to the substrate back surface 22. On a circumferential surface of the penetration hole, a metal such as a Cu, Ni, or Sn may be applied by, for example, plating. In a state of being inserted in the penetration hole, the first and second penetrating members 27 and 28 are soldered with the first and second module terminals 12c and 13. With this, the first and second module terminals 12c and 13 and the first and second conductive cooling parts 30 and 40 are electrically connected via the first and second penetrating members 27 and 28.

As the substrate 20, a resin substrate made of relatively-inexpensive glass epoxy resin or the like, a ceramic substrate, or the like can be used. Also, the substrate 20 for use can be relatively thin, such as having a thickness, for example, equal to or larger than 1.6 mm and equal to or smaller than 2.0 mm.

On the substrate 20, various electronic components other than the rectifying element module 10, and wires other than wires for the rectifying element module 10 may be arranged.

In the example of FIG. 1, the first conductive cooling part 30 electrically connects the secondary-side output (−) line Vout (−) (in the present embodiment, one example of the first external member) arranged outside the rectifying-element-module cooling unit 100 and the first module terminal 12c together. The first conductive cooling part 30 is arranged in contact with the substrate back surface 22. Here, as described above, the first module terminal 12c is electrically connected to the first conductive cooling part 30 via the first penetrating member 27. Since the first conductive cooling part 30 is electrically connected to the secondary-side output (−) line Vout (−), the secondary-side output (−) line Vout (−) and the first module terminal 12c are electrically connected via the first conductive cooling part 30. When the rectifying element module 10 has the first transistor Q1, the first source terminal S1 and the secondary-side output (−) line Vout (−) are electrically connected via the first conductive cooling part 30.

Furthermore, when the rectifying element module 10 has the first transistor Q1, the first conductive cooling part 30 cools mainly heat due to a first current passing through the first source terminal S1. Since a relatively large first current flows through the rectifying element module 10, heat occurring due to the first current is also relatively large. It can be thought that heat due to the first current occurs in the rectifying element module 10, the substrate 20 through which the first current passes, or another component. The first conductive cooling part 30 can cool heat of the substrate 20 and the rectifying element module 10 due to the first current as described above.

For the first conductive cooling part 30, a material that is conductive and has a cooling function is used. The first conductive cooling part 30 is formed of, for example, a metal such as Cu or Al.

The first conductive cooling part 30 may be formed as a wire or printed pattern, but is preferably configured as a conductive path with a plate-like appearance with a fixed shape and stiffness and, specifically, is preferably configured as a bus bar. With this, even if the rectifying element module 10 handles, for example, a large current equal to or larger than 500 A in a synchronous rectifier circuit 1, the present embodiment supports this, and achieves favorable conductivity and heat dissipation.

In the example of FIG. 1, the second conductive cooling part 40 electrically connects the secondary-side winding 2c-2d (in the present embodiment, one example of the second external member) arranged outside the rectifying-element-module cooling unit 100 and the second module terminal 13 together. The second conductive cooling part 40 is arranged in contact with the substrate back surface 22 at a position corresponding to the element body 11 and the second module terminal 13. Here, as described above, the second module terminal 13 is electrically connected to the second conductive cooling part 40 via the second penetrating member 28. Since the second conductive cooling part 40 is electrically connected to the secondary-side winding 2c-2d, the secondary-side winding 2c-2d and the second module terminal 13 are electrically connected via the second conductive cooling part 40. When the rectifying element module 10 has the first transistor Q1, the first drain terminal D1 and the second part winding finish end 2d2 of the secondary-side winding 2d (in the present embodiment, one example of the second external member) are electrically connected via the second conductive cooling part 40.

Furthermore, when the rectifying element module 10 has the first transistor Q1, the second conductive cooling part 40 cools mainly heat due to a second current passing through the first drain terminal D1. Since a relatively large second current flows through the rectifying element module 10, heat occurring due to the second current is also relatively large. It can be thought that heat due to the second current occurs in the rectifying element module 10, the substrate 20 through which the second current passes, or another component. The second conductive cooling part 40 can cool heat of the substrate 20 and the rectifying element module 10 due to the second current as described above.

For the second conductive cooling part 40, a material that is conductive and has a cooling function is used. The second conductive cooling part 40 is formed of, for example, a metal such as Cu or Al.

The second conductive cooling part 40 may be formed as a wire or printed pattern, but is preferably configured as a conductive path with a plate-like appearance with a fixed shape and stiffness and, specifically, is preferably configured as a bus bar. With this, even if the rectifying element module 10 handles, for example, a large current equal to or larger than 500 A in the synchronous rectifier circuit 1, the present embodiment can support this, and achieve favorable conductivity and heat dissipation.

The cooling promoting part 50 has at least either one of the first and second conductive cooling parts 30 and 40 directly or indirectly arranged thereon to promote cooling of at least either arranged one of the first and second conductive cooling parts 30 and 40. In the example of FIG. 1, the cooling promoting part 50 has the arrangement surface 51, which is an upper surface of the cooling promoting part 50 and is also a horizontal plane. The first conductive cooling part 30 is positioned between the substrate 20 and the cooling promoting part 50, and is arranged in contact with the substrate back surface 22 and also in contact with the arrangement surface 51 of the cooling promoting part 50. The second conductive cooling part 40 is positioned between the substrate 20 and the cooling promoting part 50 via an insulating member 80, and is arranged in contact with the substrate back surface 22 and on the arrangement surface 51 of the cooling promoting part 50 via the insulating member 80. Thus, the first conductive cooling part 30 and the second conductive cooling part 40 are electrically insulated. With this, the first module terminal 12c and the second module terminal 13 are inhibited from being short-circuited.

That is, the cooling promoting part 50 has a structure of not only promoting cooling of the first and second conductive cooling parts 30 and 40 but also, because of having conductivity, being electrically connected to one of the first and second conductive cooling parts 30 and 40 and insulatively connected to the other, in cooperation with the insulating member 80.

In the example of FIG. 1, the cooling promoting part 50 is in contact with the first conductive cooling part 30 to directly promote cooling of the first conductive cooling part 30. On the other hand, the cooling promoting part 50 indirectly promotes cooling of the second conductive cooling part 40 via the insulating member 80.

The cooling promoting part 50 is only required to promote cooling of the first and second conductive cooling parts 30 and 40, and its structure is not limited. Examples of the cooling promoting part 50 include a water-cooling heat sink capable of conducting a liquid such as water and configured of one or more fins, conduits, and so forth; an air-cooling heat sink capable of dissipating heat and configured of one or more fins; and the like.

Further specifically, as with the first and second conductive cooling parts 30 and 40, for example, the cooling promoting part 50 is preferably configured of a material having electrical and thermal conductivities, like a metal such as Cu or Al. With this, even if the rectifying element module 10 handles, for example, a large current equal to or larger than 500 A in the synchronous rectifier circuit 1, the present embodiment together with the first and second conductive cooling parts 30 and 40 supports this, and achieves favorable conductivity and heat dissipation.

Note that while the above description has been made in relation to a case in which the first transistor Q1 is arranged inside the rectifying element module 10, a brief description is made below on a case in which the second transistor Q2 is arranged inside the rectifying element module 10, focusing on different points.

The first module terminal 12c is electrically connected to the second source terminal S2. The gate pin 12a is electrically connected to the second gate terminal G2. The second module terminal 13 is electrically connected to the second drain terminal D2.

The first module terminal 12c extends to the outside of the element body 11, also extends toward the element-body back surface 11a, and is attached to the substrate 20. The first module terminal 12c is electrically connected to the first conductive cooling part 30 via the first penetrating member 27 penetrating through the substrate 20. The gate pin 12a extends to the outside of the element body 11, also extends toward the element-body back surface 11a, and is attached to the substrate 20. For example, the gate pin 12a is electrically connected to a gate signal circuit, which is not depicted, via a wire (not depicted) on the substrate 20, to receive a supply of the second gate signal g2.

Also, the first conductive cooling part 30 electrically connects the second source terminal S2 and the secondary-side output (−) line Vout (−) (in the present embodiment, one example of the first external member) together, and cools mainly heat due to a first current passing through the second source terminal S2. Also, the second conductive cooling part 40 electrically connects the second drain terminal D2 and the first part winding start end 2cl of the first part winding 2c (in the present embodiment, one example of the second external member) together, and cools heat due to a second current passing through the second drain terminal D2.

### (2) Arrangement and Structure of Entire Rectifying-Element-Module Cooling Unit

Next, the arrangement and structure of the rectifying element module 10, the substrate 20, the first conductive cooling part 30, the second conductive cooling part 40, and the cooling promoting part 50 in the rectifying-element-module cooling unit 100 are collectively and further described.

As depicted in FIG. 1 and FIG. 2, in the rectifying-element-module cooling unit 100 of the present embodiment, the cooling promoting part 50 is arranged on a lowermost portion, and the first and second conductive cooling parts 30 and 40 are arranged to be aligned in the horizontal direction (here, in the x direction) with respect to the arrangement surface of this cooling promoting part 50. The substrate 20 is arranged on the first and second conductive cooling parts 30 and 40 in the horizontal direction. On the substrate 20, the rectifying element module 10 is arranged.

The first conductive cooling part 30 is arranged between the substrate 20 and the cooling promoting part 50. Although not limited to this, the first conductive cooling part 30 is configured in a rectangular parallelepiped shape in the example of FIG. 1 and FIG. 2. The first conductive cooling part 30 has a first contact surface 30a that is a horizontal plane as an upper surface and a second contact surface 30b on a horizontal plane as a lower surface. With the substrate back surface 22 and the first contact surface 30a being in surface contact with each other and the arrangement surface 51 of the cooling promoting part 50 and the second contact surface 30b being in surface contact with each other, the first conductive cooling part 30 is placed on the cooling promoting part 50. Thus, the substrate 20, the first conductive cooling part 30, and the cooling promoting part 50 are in surface contact with one another.

In the first module terminal 12c, the tip extending toward the element-body back surface 11a is attached to the substrate 20 at the first attachment portion 25. The first attachment portion 25 is opposed to at least part of the first conductive cooling part 30 across the substrate 20. Specifically, the first conductive cooling part 30 is positioned at a portion corresponding to the tip in a direction in which the first module terminal 12c extends, that is, directly below the first module terminal 12c. The first module terminal 12c is electrically connected to the first conductive cooling part 30 via the first penetrating member 27 or the like penetrating through the substrate 20 in the thickness direction (z direction).

The second conductive cooling part 40 is arranged between the substrate 20 and the cooling promoting part 50 via the insulating member 80. Although not limited to this, the second conductive cooling part 40 is configured in a rectangular parallelepiped shape in the example of FIG. 1 and FIG. 2. The second conductive cooling part 40 has a third contact surface 40a that is a horizontal plane as an upper surface and a fourth contact surface 40b on a horizontal plane as a lower surface. The insulating member 80 is arranged between the second conductive cooling part 40 and the cooling promoting part 50. The substrate back surface 22 of the substrate 20 and the third contact surface 40a of the second conductive cooling part 40 are in surface contact with each other. Also, the fourth contact surface 40b of the second conductive cooling part 40 and the upper surface of the insulating member 80 are in surface contact with each other. Furthermore, the lower surface of the insulating member 80 and the arrangement surface 51 of the cooling promoting part 50 are in surface contact with each other.

The substrate 20 is arranged in the horizontal direction in a state of being in contact with the first contact surface 30a of the first conductive cooling part 30 and the third contact surface 40a of the second conductive cooling part 40.

The second module terminal 13 has a plate shape extending along the element-body back surface 11a, and has one surface (here, upper surface) in contact with the element-body back surface 11a. Also, the second module terminal 13 has the other surface (here, lower surface) in contact with the substrate front surface 21 of the substrate 20 and is attached to the substrate 20 at the second attachment portion 26. Here, it is configured that, in the standard state in which the first module terminal 12c extends to the outside of the element body 11 and extends toward the element-body back surface 11a and the second module terminal 13 has one surface in surface contact with the element-body back surface 11a, the other surface of the second module terminal 13 is in contact with the substrate front surface 21. Thus, the element-body back surface 11a, the second module terminal 13, the substrate 20, the second conductive cooling part 40, the insulating member 80, and the cooling promoting part 50 are in surface contact with one another.

Also, the second module terminal 13 is electrically connected to the second conductive cooling part 40 via the second penetrating member 28 penetrating through the substrate in the thickness direction (z direction) or the like. Here, the second attachment portion 26 is opposed to at least part of the second conductive cooling part 40 across the substrate 20. That is, the second conductive cooling part 40 is positioned directly below the second module terminal 13.

In the present embodiment, as depicted in FIG. 2, the plurality of rectifying element modules 10 are arranged on the substrate front surface 21 so as to be aligned in the y direction. The rectifying element modules 10 each have the first transistor Q1 or the second transistor Q2 as appropriate. The structure and arrangement of each rectifying element module 10 are similar to those described above.

### (3) Current Path

Next, a current flow in the rectifying-element-module cooling unit 100 is described. The current flow in the rectifying-element-module cooling unit 100 is the same in both a case in which the first transistor Q1 is arranged inside the rectifying element module 10 and a case in which the second transistor Q2 is arranged therein.

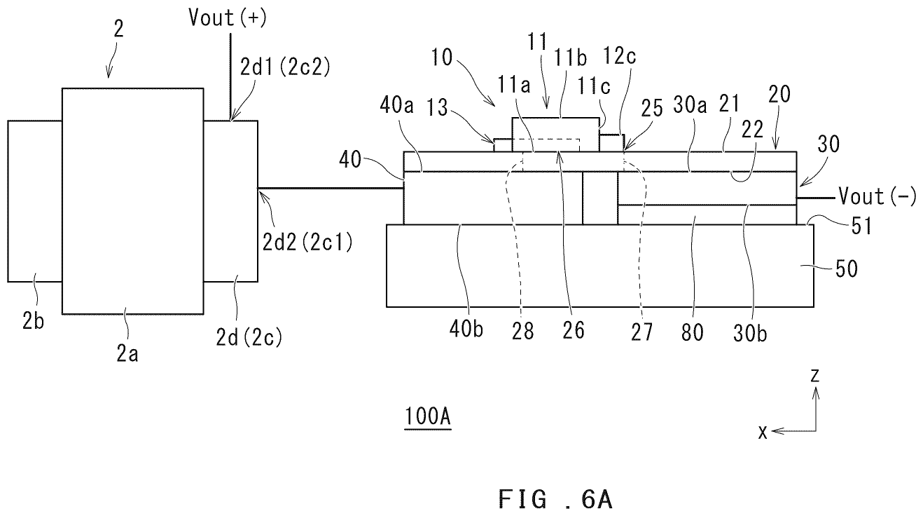

FIG. 5 is a current path diagram depicting a current flow in the rectifying-element-module cooling unit in FIG. 1.

Part of a first current path 60 of the first current from the first source terminal S1 (or second source terminal S2) via the first module terminal 12c and the first conductive cooling part 30 to the secondary-side output (−) line Vout (−) (in the present embodiment, one example of the first external member) is configured of a first penetrating current path 61 through which the first current penetrates through the substrate 20 from the substrate front surface 21 to the substrate back surface 22. The length of the first penetrating current path 61 is equivalent to a thickness t of the substrate 20 from the substrate front surface 21 to the substrate back surface 22. Also, in part of the first current path 60, a first conductive cooling path 62 through which the first current passes through the first conductive cooling part 30 is further included.

In part of a second current path 70 of the second current from the first drain terminal D1 (or second drain terminal D2) via the second module terminal 13 and the second conductive cooling part 40 to the second part winding 2d (or first part winding 2c) (in the present embodiment, one example of the second external member) is configured of a second penetrating current path 71 through which the second current penetrates through the substrate 20 from the substrate front surface 21 to the substrate back surface 22. The length of the second penetrating current path 71 is equivalent to a thickness t of the substrate 20. Also, in part of the second current path 70, a second conductive cooling path 72 through which the second current passes through the second conductive cooling part 40 is further included.

When the first transistor Q1 is turned ON and the second transistor Q2 is turned OFF, a signal from the secondary-side output (−) line Vout (−) is transferred as a first current via the first current path 60 including the first penetrating current path 61 and the first conductive cooling path 62 to the first source terminal S1, thereby letting a current flow from the first source terminal S1 to the first drain terminal D1. Next, a second current flows from the first drain terminal D1 via the second current path 70 including the second penetrating current path 71 and the second conductive cooling path 72 to the second part winding finish end 2d2 of the second part winding 2d. Then, output voltage induced at the second part winding 2d is outputted from the second part winding start end 2d1 and the secondary-side output (+) line Vout (+).

On the other hand, when the second transistor Q2 is turned ON and the first transistor Q1 is turned OFF, a signal from the secondary-side output (−) line Vout (−) is transferred as a first current via the first current path 60 including the first penetrating current path 61 and the first conductive cooling path 62 to the second source terminal S2, thereby letting a current flow from the second source terminal S2 to the second drain terminal D2. Next, a second current flows from the second drain terminal D2 via the second current path 70 including the second penetrating current path 71 and the second conductive cooling path 72 to the first part winding start end 2c1 of the first part winding 2c. Then, output voltage induced at the first part winding 2c is outputted from the first part winding finish end 2c2 and the secondary-side output (+) line Vout (+).

### (4) Operation and Effect

### (4-1) Operation and Effect by the Above-Described Current Paths and Arrangement

In the above-described rectifying element module 10, the first module terminal 12c extends to the outside of the element body 11 and extends toward the element-body back surface 11a, and the second module terminal 13 is arranged so that at least part thereof is in contact with the element-body back surface 11a. Thus, since the rectifying element module 10 can be attached to the substrate 20 in the standard state, normal attachment is only required, and no additional work is required.

Also, according to the above-described structure, part of the first current path 60 from the first and second source terminals S1 and S2 (first element terminal) via the first module terminal 12c and the first conductive cooling part 30 to the secondary-side output (−) line Vout (−) (in the present embodiment, one example of the first external member) is configured of the first penetrating current path 61. Thus, compared with a case in which the entire first current path 60 is formed as a wire on the substrate 20, heat of the substrate 20 due to the first current flowing through the substrate 20 can be suppressed. That is, with a decrease in wire length through which the first current flows in the substrate 20, heat of the substrate 20 due to the first current flowing through the wire is suppressed.

Since the wire length through which the first current flows in the substrate 20 can also be decreased by the first conductive cooling path 62 formed by the first conductive cooling part 30 serving as part of the first current path 60, heat generation of the substrate 20 is suppressed.

Furthermore, part of the second current path 70 from the first and second drain terminals D1 and D2 (second element terminal) via the second module terminal 13 and the second conductive cooling part 40 to the secondary-side winding 2d-2c (in the present embodiment, one example of the second external member) is configured of the second penetrating current path 71. Thus, compared with a case in which the entire second current path 70 is formed as a wire on the substrate 20, heat generation of the substrate 20 due to the second current flowing through the substrate 20 can be suppressed. That is, with a decrease in wire length through which the second current flows in the substrate 20, heat generation of the substrate 20 due to the second current flowing through the wire is suppressed.

Also, the above-configured rectifying element module 10 has the first and second module terminals 12c and 13 both attached to the substrate front surface 21. If wires through which the first and second currents from the first and second module terminals 12c and 13, respectively, flow are both formed on the substrate 20 such as the substrate front surface 21 and the substrate back surface 22, the first and second currents both flow through each wire on the substrate 20 cause to generate a large amount of heat on the substrate 20. To avoid this heat generation of the substrate 20, structures are considered, including: a structure in which a substrate with high thermal conductivity such as a copper substrate, a ceramic substrate, and so forth is adopted; a structure in which the thickness of the substrate is increased; and a structure in which the substrate area is increased, that is, so-called copper inlay or the like is adopted. However, in these cases, the cost of the substrate itself increases, and a decrease in size and film thickness of the substrate cannot be made. Moreover, a complex structure for cooling the substrate has to be adopted. By contrast, according to the above-described structure, by adopting the structure in which the first and second currents are let pass respectively through the first and second penetrating current paths 61 and 71, heat generated by the substrate 20 can be suppressed. As a result, a decrease in size and film thickness of the substrate 20 can be made. Also, a substrate with high thermal conductivity does not have to be adopted. Furthermore, a complex structure such as copper inlay does not have to be adopted.

Also, while heat of the first and second transistors Q1 and Q2 (rectifying elements) generated by the first current from the first and second source terminals S1 and S2 (first element terminals) is cooled by the first conductive cooling part 30, heat of the first and second transistors Q1 and Q2 (rectifying elements) generated by the second current from the first and second drain terminals D1 and D2 (second element terminals) is cooled by the second conductive cooling part 40. Thus, while the first and second source terminals S1 and S2 (first element terminals) and the first and second drain terminal D1 and D2 (second element terminals) are prevented from being short-circuited, heat generation of the first and second transistors Q1 and Q2 (rectifying elements) and the substrate 20 due to the first current and the second current can be cooled.

As described above, when the rectifying element module 10 such as a surface mount component in the standard state is attached to the substrate 20, heat itself of the substrate 20 generated by passage of the first and second currents can be suppressed. Also, even when heat is generated in the substrate 20, that heat can be cooled by the first and second conductive cooling parts 30 and 40. Thus, heat generation of the first and second transistors Q1 and Q2 (rectifying elements) due to the influence of heat of the substrate 20 can be suppressed. Also, heat of the first and second transistors Q1 and Q2 (rectifying elements) themselves can also be cooled by the first and second conductive cooling parts 30 and 40. Thus, for example, destruction of the first and second transistors Q1 and Q2 (rectifying elements) due to high junction temperature or the like can be prevented. As described above, the substrate 20 and the first and second transistors Q1 and Q2 (rectifying elements) can be cooled with the standard state of the rectifying element module 10 kept because a mode is adopted in which, while the first and second source terminals S1 and S2 (first element terminals) of the first and second transistors Q1 and Q2 (rectifying elements) are connected to the first module terminal 12c extending to the outside of the element body 11, separately from this, the first and second drain terminals D1 and D2 (second element terminals) of the first and second transistors Q1 and Q2 (rectifying elements) are connected to the second module terminal 13 in contact with the element-body back surface 11a. In this mode of the rectifying element module 10, with the rectifying element module 10, the substrate 20, the first conductive cooling part 30, the second conductive cooling part 40, and the cooling promoting part 50 arranged as described above, heat of the substrate 20 and the first and second transistors Q1 and Q2 (rectifying elements) generated by the first current and the second current can be efficiently cooled by the first conductive cooling part 30, the second conductive cooling part 40, and the cooling promoting part 50 as described above. From the above, according to the present embodiment, the rectifying-element-module cooling unit 100 for cooling the substrate 20 and the first and second transistors Q1 and Q2 (rectifying elements) can be provided.

Also, the substrate 20 and the first conductive cooling part 30 are in surface contact with each other via the substrate back surface 22 and the first contact surface 30a. Thus, the substrate 20 can be cooled by the first conductive cooling part 30 more efficiently than the case of point contact. Also, the first conductive cooling part 30 and the cooling promoting part 50 are in surface contact with each other via the second contact surface 30b and the arrangement surface 51. Thus, cooling of the first conductive cooling part 30 can be promoted by the cooling promoting part 50 more efficiently than the case of point contact.

Furthermore, while the element body 11 and the second module terminal 13 are in surface contact with each other via the element-body back surface 11a and one surface of the second module terminal 13 and the second module terminal 13 and the substrate 20 are in surface contact with each other via the other surface of the second module terminal 13 and the substrate front surface 21, the substrate 20 and the second conductive cooling part 40 are in surface contact with each other via the substrate back surface 22 and the third contact surface 40a. Thus, the element body 11 and the substrate 20 can be cooled by the second conductive cooling part 40 more efficiently than the case of point contact. Still further, the second conductive cooling part 40, the insulating member 80, and the cooling promoting part 50 are in surface contact with one another. Thus, cooling of the second conductive cooling part 40 can be promoted by the cooling promoting part 50 more efficiently than the case of point contact.

Still further, with heat generation of the substrate 20 and heat of the first generation and second transistors Q1 and Q2 (rectifying elements) suppressed, the temperature of the first conductive cooling part 30 and the second conductive cooling part 40 also decrease. Thus, a direct-current resistance Rdc of the first and second conductive cooling parts 30 and 40 can be decreased. With this, a conductive loss (I² Rdc, power loss), which is the product of the square of the current passing through the first and second conductive cooling parts 30 and 40 and the direct-current resistance Rdc, can be suppressed. Thus, power conversion efficiency in the power conversion device 1 can be improved.

Still further, when the first and second transistors Q1 and Q2 (rectifying elements) are surface mount components, the first and second transistors Q1 and Q2 (rectifying elements) and the substrate 20 can be joined by a reflow process using cream solder (reflow solder) or the like applied to the surface mount components. Thus, screwing is not required for joining the first and second transistors Q1 and Q2 (rectifying elements) to the substrate 20. With this, a process of assembling the first and second transistors Q1 and Q2 (rectifying elements) to the substrate 20 can be significantly simplified, also leading to a reduction in cost.

Still further, in general, when a transistor (rectifying element) is a discrete component, jointing the discrete component and the substrate requires the use of a flow process using melted solder. Thus, when the other components on the substrate are surface mount components, it is required to combine the flow process and the reflow process in the assembling process. By contrast, when the first and second transistors Q1 and Q2 (rectifying elements) are surface mount components, the first and second transistors Q1 and Q2 (rectifying elements) and the substrate 20 can be joined by the reflow process. Thus, when the components other than the first and second transistors Q1 and Q2 (rectifying elements) are also surface mount components, the mounting process can be performed only by a reflow process.

### (4-2) Operation and Effect by Substrate Arranged in Horizontal Direction

According to the above-described structure, the rectifying-element-module cooling unit 100 can be configured in a state in which the substrate 20 is arranged in parallel to the cooling promoting part 50 and the first and second conductive cooling parts 30 and 40. Thus, the substrate 20 can be stably arranged with respect to the cooling promoting part 50 and the first and second conductive cooling parts 30 and 40. Specifically, when the first and second module terminals 12c and 13 are attached to the substrate 20 in a surface-mount standard state, the substrate 20, the first and second conductive cooling parts 30 and 40, and the cooling promoting part 50 can be stably arranged in surface contact with one another.

### (4-3) Operation and Effect by Attachment Portion and Conductive Cooling Part Opposed to Each Other

### (a) Operation and Effect by First Attachment Portion and First Conductive Cooling Part Opposed to Each Other

According to the above-described structure, since the first attachment portion 25 is opposed to the first conductive cooling part 30 via the substrate 20, the first module terminal 12c can be connected to the first conductive cooling part 30 not via the wires on the substrate 20 but via the first penetrating current path 61 at the first attachment portion 25. Thus, heat of the substrate 20 generated by the first current flowing through the substrate 20 can be sufficiently suppressed. Thus, for example, destruction of the first and second transistors Q1 and Q2 (rectifying elements) due to heat generation of the substrate 20 can be sufficiently prevented.

### (b) Operation and Effect by Second Attachment Portion and Second Conductive Cooling Part Opposed to Each Other

According to the above-described structure, since the second attachment portion 26 is opposed to the second conductive cooling part 40 via the substrate 20, the second module terminal 13 can be connected to the second conductive cooling part 40 not via the wires on the substrate 20 but via the second penetrating current path 71 at the second attachment portion 26. Thus, heat of the substrate 20 generated by the second current flowing through the substrate 20 can be sufficiently suppressed. Thus, for example, destruction of the first and second transistors Q1 and Q2 (rectifying elements) due to heat of the substrate 20 can be sufficiently prevented.

### (4-4) Operation and Effect by Rectifying Element Module Configuring Secondary-Side Circuit of Transformer

In the above-described embodiment, the first external member is a secondary-side output line (secondary-side output (−) line Vout (−)) of the transformer 2, and the second external member is the secondary-side winding 2c-2d of the transformer 2. The rectifying element module 10 configures the secondary-side circuit 4 of the transformer 2, has a large current flowing therethrough, and tends to become large heat generation. As described above, since part of the first current path 60 of the first current flowing through the first and second source terminals S1 and S2 (first element terminals) is configured of the first penetrating current path 61, heat of the substrate 20 itself and heat of the first and second transistors Q1 and Q2 (rectifying elements) can be suppressed. Also, since part of the first current path 60 is configured of the first conductive cooling part 30, that is, the first conductive cooling path 62, heat of the substrate 20 itself and heat of the first and second transistors Q1 and Q2 (rectifying elements) can be suppressed. Similarly, part of the second current path 70 of the second current flowing through the first and second drain terminals D1 and D2 (second element terminals) is configured of the second penetrating current path 71, heat of the substrate 20 itself and heat of the first and second transistors Q1 and Q2 (rectifying elements) can be suppressed. Also, part of the second current path 70 is configured of the second conductive cooling part 40, that is, the second conductive cooling path 72, heat of the substrate 20 itself and heat of the first and second transistors Q1 and Q2 (rectifying elements) can be suppressed. Thus, the above-described rectifying-element-module cooling unit 100 is useful when applied to the secondary-side circuit 4 of the transformer 2.

Note that other examples can be as follows. In one example, the first external member is the secondary-side winding of the transformer 2, and the second external member is the secondary-side output line of the transformer 2. In another example, the first external member and the second external member are secondary-side output lines of the transformer 2, and the polarities of these output lines are different.

### (4-5) Operation and Effect by Configuration that has Cooling Promoting Part 50 Electrically Connected to One of First Conductive Cooling Part 30 and Second Conductive Cooling Part 40 and Insulatively Connected to the Other

In the above-described embodiment, the cooling promoting part 50 is electrically connected to one of the first conductive cooling part 30 and the second conductive cooling part 40 via the arrangement surface 51 and insulatively connected to the other. With this, the first conductive cooling part 30, the second conductive cooling part 40, and the cooling promoting part 50 are integrally configured, and the cooling unit can improve cooling efficiency thereof. Note that with the substrate 20 also integrated with the first conductive cooling part 30 and the second conductive cooling part 40, cooling efficiency of the cooling unit can be enhanced.

### 2. Modification of First Embodiment

### 2-1. One Example of Modification of Rectifying-Element-Module Cooling Unit

In the above-described first embodiment, the rectifying-element-module cooling unit 100 depicted in FIG. 1 and FIG. 2 has been described by way of example. However, the rectifying-element-module cooling unit is not limited to this and, for example, may be any of rectifying-element-module cooling units described below by way of example.

### (1) Another Mode of Entire Rectifying-Element-Module Cooling Unit

### (1-1) Another Mode 1

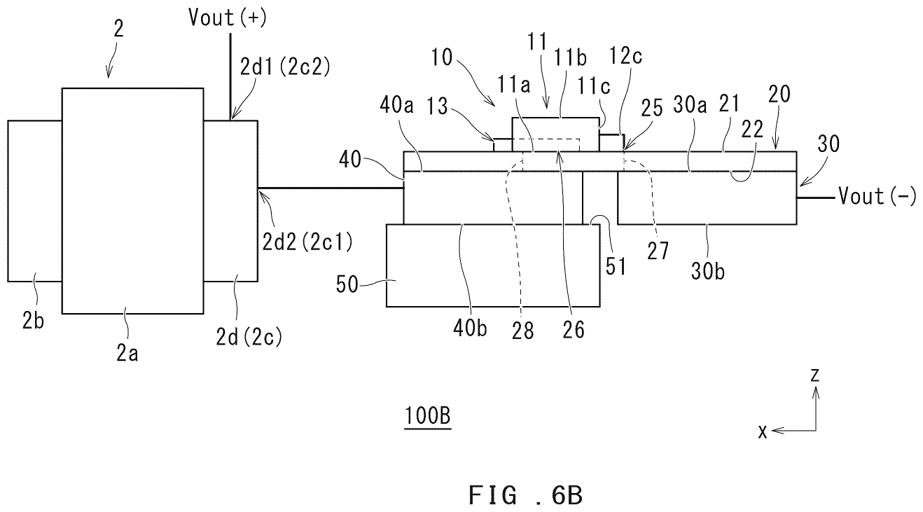

A rectifying-element-Module cooling unit 100A of another mode 1 according to the first embodiment of the present invention is described. FIG. 6A is a side view of a rectifying-element module cooling unit of another mode 1 according to the first embodiment of the present invention. The rectifying-element-module cooling unit 100A is different from the rectifying-element-module cooling unit 100 depicted in FIG. 1 in the arrangement position of the insulating member 80. Only the different point is described below. While the insulating member 80 is arranged between the second conductive cooling part 40 and the cooling promoting part 50 in the rectifying-element-module cooling unit 100, the insulating member 80 is arranged between the first conductive cooling part 30 and the cooling promoting part 50 in the rectifying-element-module cooling unit 100A. The different point is only the arrangement position of the insulating member 80, and the first and second conductive cooling parts 30 and 40 are electrically insulated from each other.

### (1-2) Another Mode 2

A rectifying-element-module cooling unit 100B of another mode 2 according to the first embodiment of the present invention is described. FIG. 6B is a side view of a rectifying-element-module cooling unit of another second mode 2 according to the first embodiment of the present invention. The rectifying-element-module cooling unit 100B is different from the rectifying-element-module cooling unit 100 depicted in FIG. 1 in the arrangement position of the cooling promoting part 50. Only the different point is described below. While the first and second conductive cooling parts 30 and 40 are arranged on the arrangement surface 51 of the cooling promoting part 50 in the rectifying-element-module cooling unit 100, only the second conductive cooling part 40 is directly arranged on the arrangement surface 51 of the cooling promoting part 50 not via the insulating member 80 in the rectifying-element-module cooling unit 100B. The first conductive cooling part 30 is not arranged on the arrangement surface 51. The first conductive cooling part 30 and the second conductive cooling part 40 are electrically insulated from each other.

### (2) Modification of Each Part of Rectifying-Element-Module Cooling Unit

### 2-1

In the above-described first embodiment, the first and second conductive cooling parts 30 and 40 are each configured in a rectangular parallelepiped shape. However, the first conductive cooling part 30 electrically connects the first module terminal 12c and the secondary-side output (−) line Vout (−) together, and is only required to cool heat due to the first current. Also, the second conductive cooling part 40 electrically connects the second module terminal 13 and the secondary-side winding 2c-2d together, and is only required to cool heat due to the second current. The shapes of the first and second conductive cooling parts 30 and 40 are not limited. For example, the first and second conductive cooling parts 30 and 40 may each have an L shape in side view.

### 2-2

In the above-described first embodiment, the first conductive cooling part 30 is positioned directly below the first module terminal 12c. However, in a range in which it is possible to suppress an adverse effect such as destruction of the rectifying element by heat due to the first current, the first module terminal 12c and the first conductive cooling part 30 may be separated to some extent. For example, the first attachment portion 25 and the first conductive cooling part 30 may be separated to some extent in the x direction. In this case, a wire for electrically connecting a separate portion between the first attachment portion 25 and the first conductive cooling part 30 is formed on the substrate front surface 21 or the substrate back surface 22. The wire is preferably short to suppress heat of the substrate 20 due to the first current passing therethrough.

Similarly, the second conductive cooling part 40 is positioned directly below the second module terminal 13. However, in a range in which it is possible to suppress an adverse effect such as destruction of the rectifying element by heat due to the second current, the second module terminal 13 and the second conductive cooling part 40 may be separated to some extent. For example, the second attachment portion 26 and the second conductive cooling part 40 may be separated to some extent in the x direction. In this case, a wire for electrically connecting a separate portion between the second attachment portion 26 and the second conductive cooling part 40 is formed on the substrate front surface 21 or the substrate back surface 22. The wire is preferably short to suppress heat of the substrate 20 due to the second current passing therethrough.

### 2-3

In the above-described first embodiment, the first and second penetrating members 27 and 28 are provided separately from the rectifying element module 10. However, the first module terminal 12c and the second module terminal 13 may each have a penetrating portion penetrating through the substrate 20 and may be connected to the first and second conductive cooling parts 30 and 40 via the penetrating portion. For example, the first module terminal 12c may have its tip portion provided with a pin-shaped penetrating portion capable of penetrating through the substrate 20, and the penetrating portion may penetrate through the substrate 20 to be electrically connected to the first conductive cooling part 30. Also, the second module terminal 13 may have the other surface provided with a pin-shaped penetrating portion capable of penetrating through the substrate 20, and the penetrating portion may penetrate through the substrate 20 to be electrically connected to the second conductive cooling part 40. In this case, the first and second penetrating members 27 and 28 can be omitted.

### 2-4

In the above-described first embodiment, the rectifying element module 10 is in a three-pin mode including the gate pin 12a, the nused pin 12b, and the first module terminal 12c. However, the number of pins of the rectifying element module 10 is not limited.

Also, in the above-described first embodiment, the unused pin 12b is configured to be shorter than the gate pin 12a and the first module terminal 12c. However, the unused pin 12b may be configured to be long. Since the unused pin 12b is not used, it is not electrically connected to the substrate 20 and other components.

### 2-5

In the above-described first embodiment, the second penetrating current path 71 electrically connects the element body 11 of the rectifying element module 10 and the cooling promoting part 50 via the second module terminal 13 and is in contact with the element body 11 of the rectifying element module 10, but may be drawn to a portion not in contact with the element body 11. With this, heat from the substrate 20 can be allowed to escape via the second penetrating current path 71 to the second conductive cooling part 40, and heat dissipation capability of the rectifying-element-module cooling unit 100 can be further improved.

In short, the second penetrating current path is only required to be configured to penetrate through the substrate from the substrate front surface to the substrate back surface, and is not limited by other specific modes.

### 3. Second Embodiment

### (1) Structure of Rectifying-Element-Module Cooling Unit

The structure of a rectifying-element-module cooling unit 200 according to a second embodiment of the present invention is described below with reference to the drawings. However, components identical or corresponding to those of the first embodiment are provided with the same reference characters and, among these and their associations, those common with those of the first embodiment are not described in detail herein unless otherwise specified below.

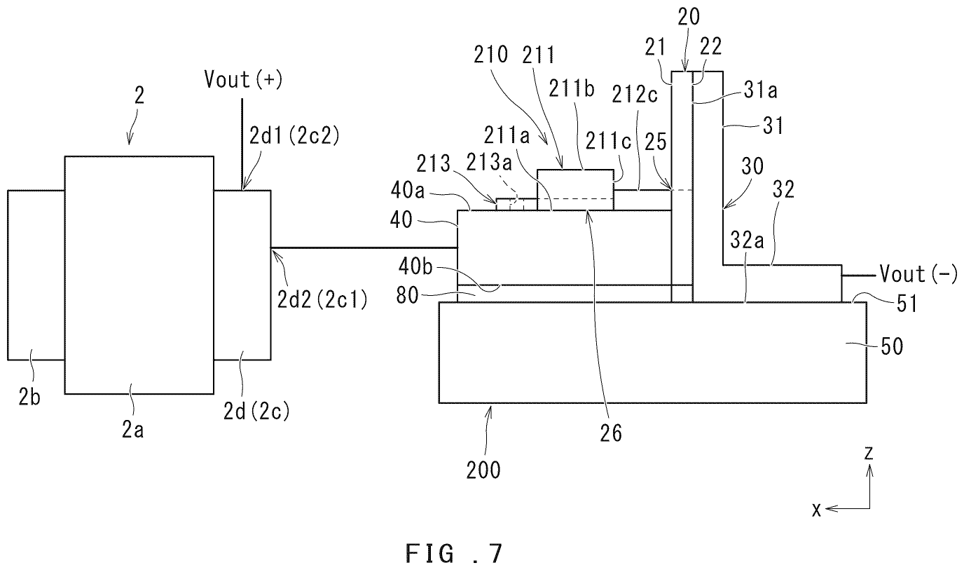

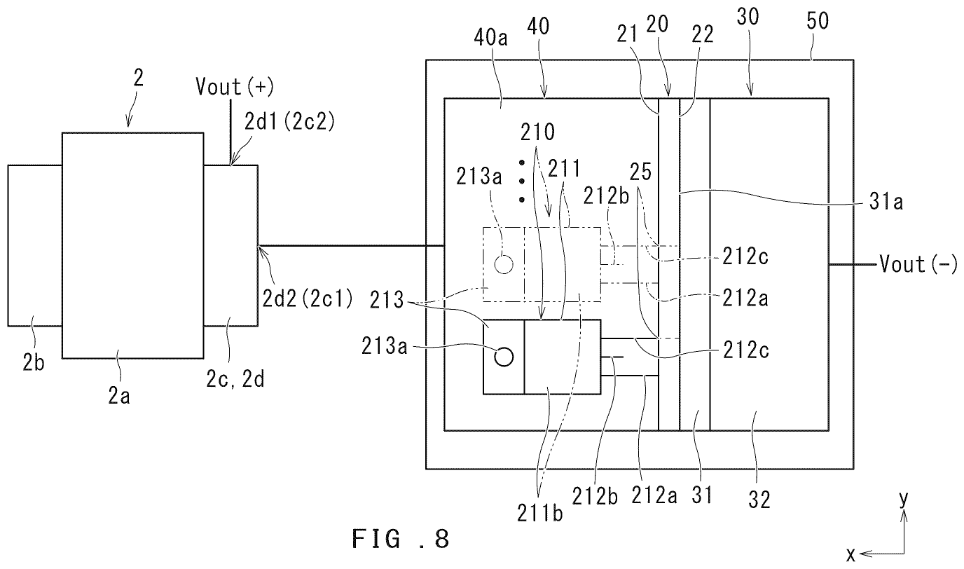

FIG. 7 is a side view of the rectifying-element-module cooling unit according to the second embodiment of the present invention. FIG. 8 is an upper view of the rectifying-element-module cooling unit according to the second embodiment of the present invention.

The rectifying-element-module cooling unit 200 according to the second embodiment has a structure different from that of the first embodiment in that the substrate 20 extends mainly in the z direction and a rectifying element module 210 as a discrete component is included in place of the rectifying element module 10 as a surface mount component.

Also in the present embodiment, the rectifying element of the rectifying element module 210 configures a synchronous rectifier circuit, and is used in the power conversion device 1 as depicted in FIG. 3.

Also in the present embodiment, the transistors are, for example, MOSFETs (metal oxide semiconductor field effect transistors). However, in place of MOSFETs, IGBTs (insulated gate bipolar transistors) or the like can be used.

Furthermore, also in the present embodiment, the transistors are preferably power transistors, and those supporting a high current at least equal to or larger than 500 A are preferable.

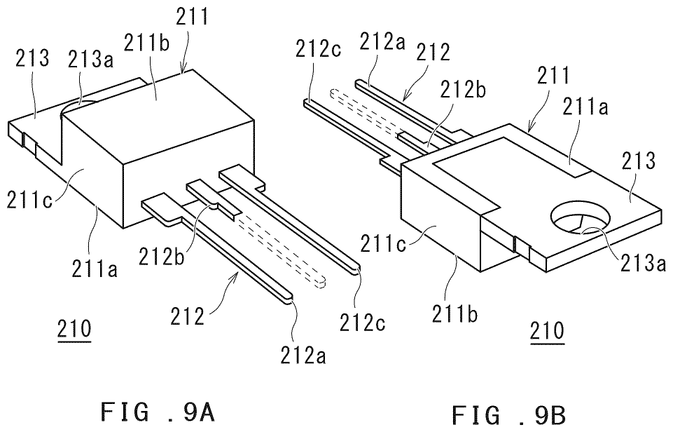

The rectifying element module 210 having the first and second transistors Q1 and Q2 (one example of the rectifying elements) is described. FIG. 9A is an upper perspective view of the rectifying element module, and FIG. 9B is a back perspective view of FIG. 9A.

As depicted in FIG. 9A and FIG. 9B, the rectifying element module 210 has an element body 211, first lead terminals 212, and a second module terminal 213. Inside the element body 211, a transistor (first transistor Q1 or second transistor Q2) is arranged. With the transistor sealed with resin, the element body 211 is configured. The element body 211 has an element-body back surface 211a, an element-body front surface 211b, and element-body side surfaces 211c. In the present embodiment, the element body 211 has a substantially rectangular parallelepiped shape. The element-body back surface 211a is the back surface of the element body 211. The element-body front surface 211b is the front surface of the element body 211 opposed to the element-body back surface 211a. The element-body side surfaces 211c are side surfaces of the element body 211, which are surfaces of the element body 11 other than the element-body back surface 211a and the element-body front surface 211b.

In the following, the rectifying element module 210 is described on the assumption that the first transistor Q1 is arranged inside the element body 211.

In the present embodiment, the first lead terminals 212 extend from the element body 211. The first lead terminals 212 are formed of a conductive material, for example, a metal having copper as a main component. The first lead terminals 212 include, for example, a gate pin 212a, an unused pin 212b, and a first module terminal 212c. The gate pin 212a, the unused pin 212b and the first module terminal 212c are aligned in sequence in a direction along the element-body back surface 211a. The unused pin 212b is cut and is not used. The first module terminal 212c is electrically connected to the first source terminal S1. The gate pin 212a is electrically connected to the first gate terminal G1. The gate pin 212a and the first module terminal 212c extend from one of the element-body side surfaces 211c to the outside of the element body 211 along the element-body back surface 211a. Also, one of the element-body side surfaces 211c from which the gate pin 212a and the first module terminal 212c are extended is a surface opposed to a side on which part of the second module terminal 213 protrudes from the element body 211. That is, the direction in which the first lead terminals 212 extend from the element body 211 and the direction in which the second module terminal 213 protrudes from the element body 211 are opposed to each other. Note that in FIG. 7 and others, for convenience of description, only the first module terminal 212c among the first lead terminals 212 is depicted.

The second module terminal 213 is electrically connected to the first drain terminal D1. The second module terminal 213 is arranged at least partially in contact with the element-body back surface 211a. In the present embodiment, the second module terminal 213 has a plate shape extending along the element-body back surface 211a, and is arranged partially in surface contact with the element-body back surface 211a. The second module terminal 213 is arranged so as to be flush with the element-body back surface 211a. Also, the second module terminal 213 has the remaining portion not in contact with the element-body back surface 211a extending from one element-body side surface 211c along the element-body back surface 211a to the outside of the element body 211 in a direction opposite to a direction in which the first module terminal 212c extends from the element body 211. A portion of the second module terminal 213 extending to the outside of the element body 211 is provided with a fastening hole 213a into which a fastening fixture (not depicted) for attaching the rectifying element module 210 to the substrate 20. The second module terminal 213 as described above is formed of a conductive material, for example, a metal having copper as a main component.

In the above-described rectifying element module 210, the first module terminal 212c extends along the element-body back surface 211a to the outside of the element body 211, and at least part of the second module terminal 213 is arranged along the element-body back surface 211a. The above-described rectifying element module 210 is a discrete component in a standard state in which, for example, the first module terminal 212c extends to the outside of the element body 211 without being bent. The standard state in which the first module terminal 212 is not bent is, for example, a state in which the standard state of the discrete component is kept in which the first module terminal 212c extends from the element body 211 to the outside while being along the element-body back surface 211a. Also, the state in which the first module terminal 212c is not bent includes a state in which, from the standard state of the discrete component, the first module terminal 212c is not warped to the extent of going toward the element-body back surface 211a but the first module terminal 212c is bent to some extent in a direction not along the element-body back surface 211a. In the present embodiment, a state in which the first module terminal 212c extends along the element-body back surface 211a to the outside of the element body 211 is taken as a standard state. In the present embodiment, as with the first module terminal 212c, the gate pin 212a also extends along the element-body back surface 211a to the outside of the element body 211.

As depicted in FIG. 7 and FIG. 8, the substrate 20 is for arranging the rectifying element module 210. The substrate 20 is formed in a plate shape, and has the substrate front surface 21 and the substrate back surface 22. In the present embodiment, the substrate 20 stands with respect to the cooling promoting part 50. Here, the substrate 20 is provided in the vertical direction. Thus, the substrate front surface 21 and the substrate back surface 22 are along the vertical plane. The rectifying element module 210 is arranged on a substrate front surface 21 side of the substrate 20. The first module terminal 212c extends in a perpendicular direction (here, the x direction) with respect to the substrate front surface 21, and is attached to the substrate 20 at the first attachment portion 25. Furthermore, the first module terminal 212c is inserted into a pin hole, which will be described further below, and penetrates through the substrate 20 from the substrate front surface 21 to the substrate back surface 22 to be electrically connected to the first conductive cooling part 30. Although omitted in FIG. 7, as with the first module terminal 212c, the gate pin 212a extends in a perpendicular direction with respect to the substrate front surface 21 and is attached to the substrate 20. For example, the gate pin 212a is electrically connected to a gate signal circuit, which is not depicted, via a wire (not depicted) on the substrate 20, to receive a supply of the first gate signal g1.

The element body 211 and the second module terminal 213 are separated from the substrate front surface 21 leftward in the drawing in the present embodiment. Here, the first module terminal 212c is attached to the substrate front surface 21 in the standard state of extending along the element-body back surface 211a. Thus, the element body 211 and the second module terminal 213 are positioned in a direction away from the substrate 20 with respect to the first attachment portion 25 where the first module terminal 212c is attached to the substrate 20.

In the substrate 20, at least one pin hole (not depicted) penetrating through the substrate 20 from the substrate front surface 21 to the substrate back surface 22. Said at least one pin hole is provided so as to correspond to the first module terminal 212c. Said at least one pin hole may be provided so as to correspond to the unused pin 212b and the gate pin 212a. The pin hole may have its circumferential surface coated with a metal such as Cu, Ni, or Sn by, for example, plating. The first module terminal 212c is soldered in a state of being inserted in the pin hole, thereby fixing the rectifying element module 210 to the substrate 20. The first module terminal 212c penetrates through the substrate 20 via the pin hole to be electrically connected to the first conductive cooling part 30 positioned on the substrate back surface 22.

In the example of FIG. 7, the first conductive cooling part 30 electrically connects the secondary-side output (−) line Vout (−) (in the present embodiment, one example of the first external member) arranged outside the rectifying-element-module cooling unit 200 and the first module terminal 212c together. The first conductive cooling part 30 is arranged in contact with the substrate back surface 22. Here, as described above, the first module terminal 212c is electrically connected to the first conductive cooling part 30 in a state of being inserted into the pin hole penetrating through the substrate 20 and fixed. For example, the tip of the first module terminal 212c protrudes to a substrate back surface 22 side of the substrate 20, and this protruding portion makes contact with the first conductive cooling part 30, thereby causing the first module terminal 212c to be electrically connected to the first conductive cooling part 30. Since the first conductive cooling part 30 is electrically connected to the secondary-side output (−) line Vout (−), the secondary-side output (−) line Vout (−) and the first module terminal 212c are electrically connected via the first conductive cooling part 30. When the rectifying element module 210 has the first transistor Q1, the first source terminal S1 and the secondary-side output (−) line Vout (−) are electrically connected via the first conductive cooling part 30.

Furthermore, when the rectifying element module 210 has the first transistor Q1, the first conductive cooling part 30 cools mainly heat due to a first current passing through the first source terminal S1. Since a relatively large first current flows through the rectifying element module 210, heat occurring due to the first current is also relatively large. It can be thought that heat due to the first current occurs in the rectifying element module 210, the substrate 20 through which the first current passes, or another component. The first conductive cooling part 30 can cool heat of the substrate 20 and the rectifying element module 210 due to the first current as described above.

As with the first embodiment, in the example of FIG. 7, the second conductive cooling part 40 electrically connects the secondary-side winding 2c-2d (in the present embodiment, one example of the second external member) arranged outside the rectifying-element-module cooling unit 200 and the second module terminal 213 together. Specifically, when the rectifying element module 210 has the first transistor Q1, the second conductive cooling part 40 electrically connects the first drain terminal D1 and the second part winding finish end 2d2 of the second part winding 2d (in the present embodiment, one example of the second external member). As with the rectifying element module 210, the second conductive cooling part 40 is arranged on the substrate front surface 21 side. The second module terminal 213 is attached in contact with the second conductive cooling part 40. This contact portion is hereinafter referred to as a second attachment portion 26.

Furthermore, when the rectifying element module 210 has the first transistor Q1, the second conductive cooling part 40 cools mainly heat due to a second current passing through the first drain terminal D1. Since a relatively large second current flows through the rectifying element module 210, heat occurring due to the second current is also relatively large. It can be thought that heat due to the second current occurs in the rectifying element module 210, the substrate 20 through which the second current passes, or another component. The second conductive cooling part 40 can cool the heat of the substrate 20 and the rectifying element module 210 due to the second current as described above.

The cooling promoting part 50 has at least either one of the first and second conductive cooling parts 30 and 40 directly or indirectly arranged thereon to promote cooling of at least either arranged one of the first and second conductive cooling parts 30 and 40. In the example of FIG. 7, the cooling promoting part 50 has an arrangement surface 51, which is an upper surface of the cooling promoting part 50 and is also a horizontal plane. The first conductive cooling part 30 is arranged in contact with the substrate back surface 22 and also in contact with the arrangement surface 51 of the cooling promoting part 50. Also, the second conductive cooling part 40 is indirectly arranged on the arrangement surface 51 of the cooling promoting part 50 in a state of being insulated from the cooling promoting part 50 via the insulating member 80. Thus, the first conductive cooling part 30 and the second conductive cooling part 40 are electrically insulated. With this, the first module terminal 212c and the second module terminal 213 are inhibited from being short-circuited.

That is, the cooling promoting part 50 has a structure of not only promoting cooling of the first and second conductive cooling parts 30 and 40 but also, because of having conductivity, being electrically connected to one of the first and second conductive cooling parts 30 and 40 and insulatively connected to the other, in cooperation with the insulating member 80.

In the example of FIG. 7, the cooling promoting part 50 is in contact with the first conductive cooling part 30 to directly promote cooling of the first conductive cooling part 30. On the other hand, the cooling promoting part 50 indirectly promotes cooling of the second conductive cooling part 40 via the insulating member 80. Note that the substrate 20 is arranged on the arrangement surface 51 in a state of being insulated from the cooling promoting part 50 via the insulating member 80.

As with the first embodiment, the cooling promoting part 50 is only required to promote cooling of the first and second conductive cooling parts 30 and 40, and its structure is not limited. Examples of the cooling promoting part 50 include a water-cooling heat sink capable of conducting a liquid such as water and configured of one or more fins, conduits, and so forth; an air-cooling heat sink capable of dissipating heat and configured of one or more fins; and the like.

Note that while the above description has been made in relation to a case in which the first transistor Q1 is arranged inside the rectifying element module 210, a brief description is made below on a case in which the second transistor Q2 is arranged inside the rectifying element module 210, focusing on different points.

The first module terminal 212c is electrically connected to the second source terminal S2. The gate pin 212a is electrically connected to the second gate terminal G2. The second module terminal 213 is electrically connected to the second drain terminal D2.

The first module terminal 212c extends in a perpendicular direction with respect to the substrate front surface 21, and penetrates through the substrate 20 to be electrically connected to the first conductive cooling part 30. The gate pin 212a extends to in a perpendicular direction with respect to the substrate front surface 21 and, for example, is electrically connected to a gate signal circuit, which is not depicted, via a wire (not depicted) on the substrate 20, to receive a supply of a the second gate signal g2.

Also, the first conductive cooling part 30 electrically connects the second source terminal S2 and the secondary-side output (−) line Vout (−) (in the present embodiment, one example of the first external member) together, and cools mainly heat due to a first current passing through the second source terminal S2. Also, the second conductive cooling part 40 electrically connects the second drain terminal D2 and the first part winding start end 2cl of the first part winding 2c (in the present embodiment, one example of the second external member) together, and cools heat due to a second current passing through the second drain terminal D2.

### (2) Arrangement and Structure of Entire Rectifying-Element-Module Cooling Unit

Next, the arrangement and structure of the rectifying element module 210, the substrate 20, the first conductive cooling part 30, the second conductive cooling part 40, and the cooling promoting part 50 in the rectifying-element-module cooling unit 200 are collectively and further described.

As depicted in FIG. 7 and FIG. 8, in the rectifying-element-module cooling unit 200 of the present embodiment, the cooling promoting part 50 is arranged on a lowermost portion. The substrate 20 stands in a perpendicular direction (in the present embodiment, the z direction) with respect to the arrangement surface 51 of this cooling promoting part 50. On the cooling promoting part 50, the rectifying element module 210 and the second conductive cooling part 40 are arranged on a substrate front surface 21 side of the substrate 20, and the first conductive cooling part 30 is arranged on the substrate back surface 22 side.

The first conductive cooling part 30 is in contact with the substrate back surface 22 and also is in contact with the arrangement surface 51 of the cooling promoting part 50 to be placed on the cooling promoting part 50. The first conductive cooling part 30 is not limited to this, but, in the example of FIG. 7 and FIG. 8, is configured of a first portion 31 extending in a plate shape along a vertical plane (a plane perpendicular to the x-y plane), a second portion 32 extending in a plate shape along a horizontal direction (a plane parallel to the x-y plane) to have an L shape in side view. The first portion 31 has a first portion contact surface 31a in a plane shape in surface contact with the substrate back surface 22, and the second portion 32 has a second portion contact surface 32a in a plane shape in surface contact with the arrangement surface 51 of the cooling promoting part 50.

The first module terminal 212c is attached to the substrate 20 at the first attachment portion 25, and penetrates through the substrate 20 in a thickness direction (x direction) from the substrate front surface 21 to the substrate back surface 22. The first attachment portion 25 is opposed to at least part of the first portion 31 across the substrate 20. Specifically, the first portion 31 is positioned at a portion corresponding to the tip of the first module terminal 212c in its extending direction, that is, next to the first module terminal 212c. The first module terminal 212c is electrically connected to the first portion 31 directly or via solder and, in turn, electrically connected to the first conductive cooling part 30 including the first and second portions 31 and 32.

The second conductive cooling part 40 is placed on the cooling promoting part 50 via the insulating member 80 on the substrate front surface 21 side. In the example of FIG. 7 and FIG. 8, the second conductive cooling part 40 is configured to be in contact with the substrate front surface 21 of the substrate 20 and in a parallelepiped shape extending tin a perpendicular direction (x direction in FIG. 7), and has a third contact surface 40a (here, an lower surface) as a horizontal plane and a fourth contact surface 40b (here, lower surface). as a horizontal plane. The insulating member 80 is arranged so as to correspond to a portion of the arrangement surface 51 where the second conductive cooling part 40 and the substrate 20 are placed. In a state in which the fourth contact surface 40b is in surface contact with the insulating member 80, the second conductive cooling part 40 is placed on the cooling promoting part 50 via the insulating member 80. Also, the rectifying element module 210 is arranged in a state in which the second module terminal 213 is in surface contact with the third contact surface 40a of the second conductive cooling part 40.

As described above, while the first conductive cooling part 30 is arranged in contact with the substrate back surface 22, the second conductive cooling part 40 is arranged in contact with the substrate front surface 21. However, the second conductive cooling part 40 is not electrically connected to the substrate 20, and the first conductive cooling part 30 and the second conductive cooling part 40 are not electrically connected together. As described above, with the first and second conductive cooling parts 30 and 40 brought into contact with the substrate 20 from both the substrate front surface 21 and the substrate back surface 22 to support the substrate 20, the substrate 20 can be caused to stably stand in a perpendicular direction with respect to the arrangement surface 51 of the cooling promoting part 50.

The second module terminal 213 has a plate shape extending along the element-body back surface 211a, and has one surface (here, an upper surface) in surface contact with the element-body back surface 211a. Also, the second module terminal 213 has the other surface (here, a lower surface) in surface contact with the third contact surface 40a of the second conductive cooling part 40 and is attached to the second conductive cooling part 40 at the second attachment portion 26. Here, it is configured that, in a state in which the first module terminal 212c extends in a perpendicular direction with respect to the substrate 20, the other surface of the second module terminal 213 is in surface contact with the third contact surface 40a of the second conductive cooling part 40. The element-body back surface 211a, the second module terminal 213, the second conductive cooling part 40, the insulating member 80, and the cooling promoting part 50 are in surface contact with one another.

In the present embodiment, as depicted in FIG. 8, the plurality of rectifying element modules 210 are arranged on the substrate front surface 21 so as to be aligned in the y direction. The rectifying element modules 210 each have the first transistor Q1 or the second transistor Q2 as appropriate. The structure and arrangement of each rectifying element module 210 are similar to those described above.

### (3) Current Path

Next, a current flow in the rectifying-element-module cooling unit 200 is described. The current flow in the rectifying-element-module cooling unit 200 is the same in both a case in which the first transistor Q1 is arranged inside the rectifying element module 210 and a case in which the second transistor Q2 is arranged therein.

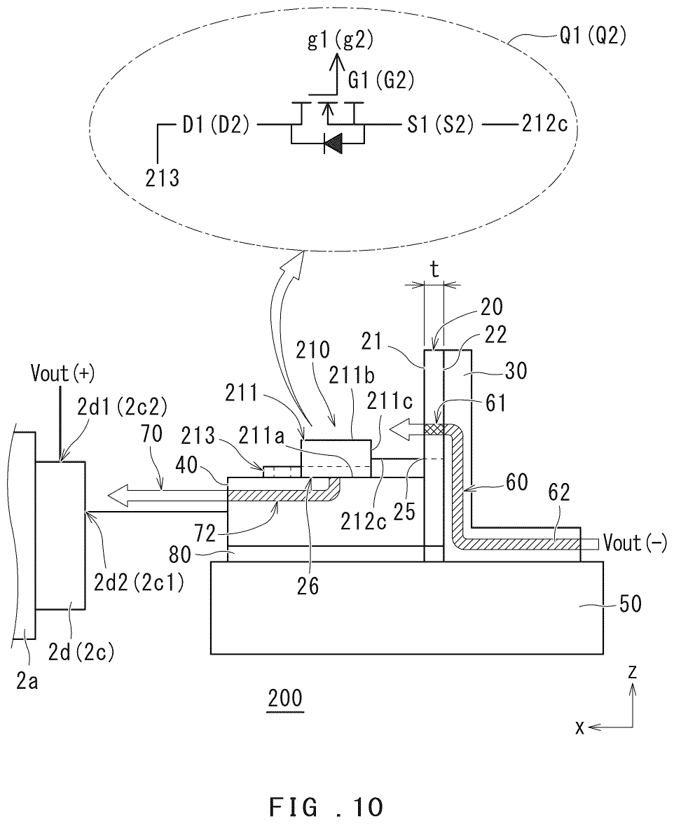

FIG. 10 is a current path diagram depicting a current flow in the rectifying-element-module cooling unit in FIG. 7.

Part of the first current path 60 of the first current from the first source terminal S1 (or second source terminal S2) via the first module terminal 212c and the first conductive cooling part 30 to the secondary-side output (−) line Vout (−) (in the present embodiment, one example of the first external member) is configured of a first penetrating current path 61 through which the first current penetrates through the substrate 20 from the substrate front surface 21 to the substrate back surface 22. The length of the first penetrating current path 61 is equivalent to a thickness t of the substrate 20 from the substrate front surface 21 to the substrate back surface 22. Also, in part of the first current path 60, a first conductive cooling path 62 through which the first current passes through the first conductive cooling part 30 is further included.

Part of a second current path 70 of the second current from the first drain terminal D1 (or second drain terminal D2) via the second module terminal 13 and the second conductive cooling part 40 to the second part winding 2d (or first part winding 2c) (in the present embodiment, one example of the second external member) is configured of a second conductive cooling path 72 through which the second current passes through the second conductive cooling part 40 not via the substrate 20.

When the first transistor Q1 is turned ON and the second transistor Q2 is turned OFF, a signal from the secondary-side output (−) line Vout (−) is transferred as a first current via the first current path 60 including the first penetrating current path 61 and the first conductive cooling path 62 to the first source terminal S1, thereby letting a current flow from the first source terminal S1 to the first drain terminal D1. Next, a second current flows from the first drain terminal D1 via the second current path 70 including the second conductive cooling path 72 to the second part winding finish end 2d2 of the second part winding 2d. Then, output voltage induced at the second part winding 2d is outputted from the second part winding start end 2d1 and the secondary-side output (+) line Vout (+).

On the other hand, when the second transistor Q2 is turned ON and the first transistor Q1 is turned OFF, a signal from the secondary-side output (−) line Vout (−) is transferred as a first current via the first current path 60 including the first penetrating current path 61 and the first conductive cooling path 62 to the second source terminal S2, thereby letting a current flow from the second source terminal S2 to the second drain terminal D2. Next, a second current flows from the second drain terminal D2 via the second current path 70 including the second conductive cooling path 72 to the first part winding start end 2cl of the first part winding 2c. Then, output voltage induced at the first part winding 2c is outputted from the first part winding finish end 2c2 and the secondary-side output (+) line Vout (+).

### (4) Operation and Effect

### (4-1) Operation and Effect by the Above-Described Current Paths and Arrangement

According to the above-described structure, the first module terminal 212c can be attached to the substrate 20 in the standard state of the rectifying element module 210 with the first module terminal 212c not bent. Thus, effort of bending process can be eliminated or reduced.

Also, according to the above-described structure, part of the first current path 60 from the first and second source terminals S1 and S2 (first element terminal) via the first module terminal 212c and the first conductive cooling part 30 to the secondary-side output (−) line Vout (−) (in the present embodiment, one example of the first external member) is configured of the first penetrating current path 61. Thus, compared with a case in which the entire first current path 60 is formed as a wire on the substrate 20, heat generation of the substrate 20 due to the first current flowing through the substrate 20 can be suppressed. That is, with a decrease in wire length through which the first current flows in the substrate 20, heat of the substrate 20 generated by the first current flowing through the wire is suppressed.

Also, with the first conductive cooling path 62 formed of the first conductive cooling part 30 assuming part of the first current path 60, the wire length through which the first current flows in the substrate 20 can also be decreased. Thus, heat of the substrate 20 is suppressed. Since the wire length through which the first current flows in the substrate 20 can also be decreased by the first conductive cooling path 62 formed by the first conductive cooling part 30 serving as part of the first current path 60, heat generation of the substrate 20 is suppressed.

Furthermore, part of the second current path 70 of the second current from the first and second drain terminals D1 and D2 (second element terminal) via the second module terminal 213 and the second conductive cooling part 40 to the secondary-side winding 2d-2c (in the present embodiment, one example of the second external member) is configured of the second conductive cooling path 72 formed of the second conductive cooling part 40 not via the substrate 20. Thus, compared with a case in which the entire second current path 70 is formed as a wire on the substrate 20, heat of the substrate 20 generated by the second current flowing through the substrate 20 can be suppressed.

Also, while heat of the first and second transistors Q1 and Q2 (rectifying elements) generated by the first current from the first and second source terminals S1 and S2 (first element terminals) is cooled by the first conductive cooling part 30, heat of the first and second transistors Q1 and Q2 (rectifying elements) generated by the second current from the first and second drain terminals D1 and D2 (second element terminals) is cooled by the second conductive cooling part 40. Thus, while the first and second source terminals S1 and S2 (first element terminals) and the first and second drain terminal D1 and D2 (second element terminals) are prevented from being short-circuited, heat generation of the first and second transistors Q1 and Q2 (rectifying elements) and the substrate 20 due to the first current and the second current can be cooled.

As described above, when the rectifying element module 210 such as a discrete component is attached to the substrate 20 in the standard state without the first module terminal 212c being bent, heat itself of the substrate 20 generated by passage of the first and second currents can be suppressed. Also, even when heat is generated in the substrate 20, that heat can be cooled by the first and second conductive cooling parts 30 and 40. Thus, heat generation of the first and second transistors Q1 and Q2 (rectifying elements) due to the influence of heat of the substrate 20 can be suppressed. Also, heat generation of the first and second transistors Q1 and Q2 (rectifying elements) themselves can also be cooled by the first and second conductive cooling parts 30 and 40. Thus, for example, destruction of the first and second transistors Q1 and Q2 (rectifying elements) due to high junction temperature or the like can be prevented. As described above, the substrate 20 and the first and second transistors Q1 and Q2 (rectifying elements) can be cooled with the standard state of the rectifying element module 210 kept because a mode is adopted in which, while the first and second source terminals S1 and S2 (first element terminals) of the first and second transistors Q1 and Q2 (rectifying elements) are connected to the first module terminal 212c extending to the outside of the element body 211, separately from this, the first and second drain terminals D1 and D2 (second element terminals) of the first and second transistors Q1 and Q2 (rectifying elements) are connected to the second module terminal 213 in contact with the element-body back surface 211a. In this mode of the rectifying element module 210, with the rectifying element module 210, the substrate 20, the first conductive cooling part 30, the second conductive cooling part 40, and the cooling promoting part 50 arranged as described above, heat of the substrate 20 and the first and second transistors Q1 and Q2 (rectifying elements) generated by the first current and the second current can be efficiently cooled by the first conductive cooling part 30, the second conductive cooling part 40, and the cooling promoting part 50, as described above. From the above, according to the present embodiment, the rectifying-element-module cooling unit 200 for cooling the substrate 20 and the first and second transistors Q1 and Q2 (rectifying elements) can be provided.

Also, the substrate 20 and the first conductive cooling part 30 are in surface contact with each other via the substrate back surface 22 and the first portion contact surface 31a. Thus, the substrate 20 can be cooled by the first conductive cooling part 30 more efficiently than the case of point contact. Also, the first conductive cooling part 30 and the cooling promoting part 50 are in surface contact with each other via the second portion contact surface 32a and the arrangement surface 51. Thus, cooling of the first conductive cooling part 30 can be promoted by the cooling promoting part 50 more efficiently than the case of point contact.

Furthermore, while the element body 211 and the second module terminal 213 are in surface contact with each other via the element-body back surface 211a and one surface of the second module terminal 213, the second module terminal 213 and the second conductive cooling part 40 are in surface contact with each other via the other surface of the second module terminal 213 and the third contact surface 40a. Thus, the element body 211 can be cooled by the second conductive cooling part 40 more efficiently than the case of point contact. Still further, the second conductive cooling part 40 and the cooling promoting part 50 are in surface contact with each other via the insulating member 80 via the fourth contact surface 40b and the arrangement surface 51. Thus, cooling of the second conductive cooling part 40 can be promoted by the cooling promoting part 50 more efficiently than the case of point contact. Note that since the second conductive cooling part 40 is arranged so as to be insulated from but in contact with the substrate 20, the substrate 20 can be cooled also by the second conductive cooling part 40.

Still further, with heat generation of the substrate 20 and heat generation of the first and second transistors Q1 and Q2 (rectifying elements) suppressed, the temperature of the first conductive cooling part 30 and the second conductive cooling part 40 also decrease. Thus, a direct-current resistance Rdc of the first and second conductive cooling parts 30 and 40 can be decreased. With this, a conductive loss (I² Rdc, power loss), which is the product of the square of the current passing through the first and second conductive cooling parts 30 and 40 and the direct-current resistance Rdc, can be suppressed. Thus, power conversion efficiency in the power conversion device 1 can be improved.

### (4-2) Operation and Effect by Substrate Standing

According to the above-described structure, the substrate 20 stands in the perpendicular direction with respect to the cooling promoting part 50. Across this substrate 20, the first conductive cooling part 30 on the substrate back surface 22 side and the second conductive cooling part 40 on the substrate front surface 21 side are arranged so as to be opposed to each other. With this, with the first module terminal 212c attached to the standing substrate 20 in the not-bent standard state, the first current passing from the first module terminal 212c to the substrate back surface side 22 side is guided by the first conductive cooling part 30 to the secondary-side output (−) line Vout (−) (in the present embodiment, one example of the first external member), and heat generated by the first current can be cooled by the first conductive cooling part 30. On the other hand, the second current passing through the second module terminal 213 arranged away from the substrate 20 on the substrate front surface 21 side is guided by the second conductive cooling part 40 to the secondary-side winding 2d-2c (in the present embodiment, one example of the second external member), and heat generation due to the second current can be cooled by the second conductive cooling part 40.

### (4-3) Operation and Effect by First Attachment Portion and First Conductive Cooling Part Opposed to Each Other

According to the above-described structure, since the first attachment portion 25 is opposed to the first conductive cooling part 30 via the substrate 20, the first module terminal 212c can be connected to the first conductive cooling part 30 not via the wires on the substrate 20 but via the first penetrating current path 61 at the first attachment portion 25. Thus, heat of the substrate 20 generated by the first current flowing through the substrate 20 can be sufficiently suppressed. Thus, for example, destruction of the first and second transistors Q1 and Q2 (rectifying elements) due to heat generation of the substrate 20 can be sufficiently prevented.

### (4-4) Operation and Effect by Rectifying Element Module Configuring Secondary-Side Circuit of Transformer

In the above-described embodiment, the first external member is the secondary-side output line (secondary-side output (−) line Vout (−)) of the transformer 2, and the second external member is the secondary-side winding 2c-2d of the transformer 2. The rectifying element module 210 configures the secondary-side circuit 4 of the transformer 2, has a large current flowing therethrough, and tends to become large of heat generation. As described above, since part of the first current path 60 of the first current flowing through the first and second source terminals S1 and S2 (first element terminals) is configured of the first penetrating current path 61, heat of the substrate 20 itself and heat of the first and second transistors Q1 and Q2 (rectifying elements) can be suppressed. Also, since part of the first current path 60 is configured of the first conductive cooling part 30, that is, the first conductive cooling path 62, heat of the substrate 20 itself and heat of the first and second transistors Q1 and Q2 (rectifying elements) can be suppressed. Also, part of the second current path 70 of the second current flowing through the first and second drain terminals D1 and D2 (second element terminals) is configured of the second conductive cooling part 40, that is, the second conductive cooling path 72, heat generation of the substrate 20 and the first and second transistors Q1 and Q2 (rectifying elements) can be suppressed. Thus, the rectifying-element-module cooling unit 200 is useful when applied to the secondary-side circuit 4 of the transformer 2.

Note that other examples can be as follows. In one example, the first external member is the secondary-side winding of the transformer 2, and the second external member is the secondary-side output line of the transformer 2. In another example, the first external member and the second external member are secondary-side output lines of the transformer 2, and the polarities of output lines are different.

### 4. Modification of Second Embodiment

### 2-1. One Example of Modification of Rectifying-Element-Module Cooling Unit

In the above-described embodiment, the rectifying-element-module cooling unit 200 depicted in FIG. 7 and FIG. 8 is described by way of example. However, the rectifying-element-module cooling unit is not limited to this and, for example, may be any of rectifying-element-module cooling units described below by way of example.

### (1) Another Mode of Entire Rectifying-Element-Module Cooling Unit

### (1-1) Anther Mode 1

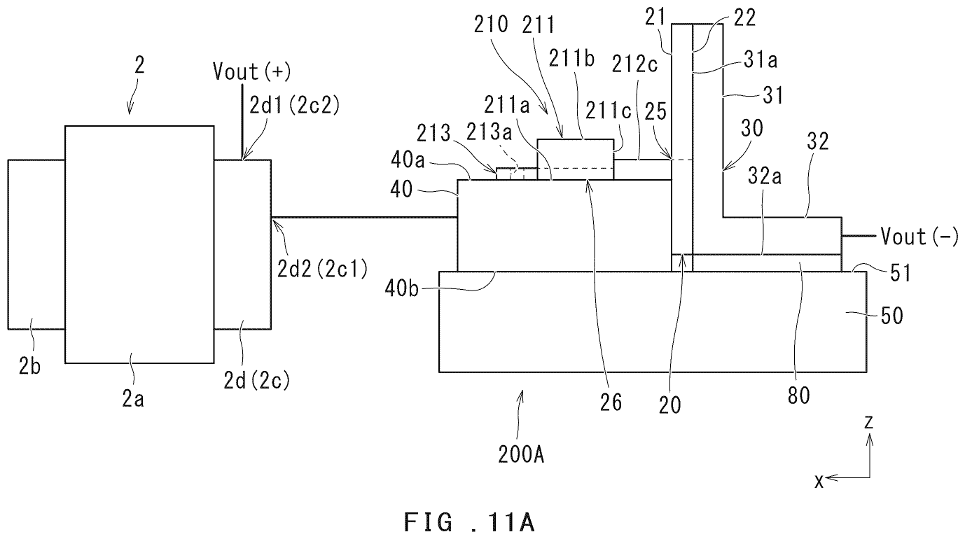

A rectifying-element module cooling unit 200A of another mode 1 according to the second embodiment of the present invention is described. FIG. 11A is a side view of a rectifying-element module cooling unit of another mode 1 according to the second embodiment of the present invention. The rectifying-element-module cooling unit 200A is different from the rectifying-element-module cooling unit 200 depicted in FIG. 7 in the arrangement position of the insulating member 80. Only the different point is described below. While the insulating member 80 is arranged between the second conductive cooling part 40 and the substrate 20 and the cooling promoting part 50 in the rectifying-element-module cooling unit 200, the insulating member 80 is arranged between the first conductive cooling part 30 and the substrate 20 and the cooling promoting part 50 in the rectifying-element-module cooling unit 200A. The different point is only the arrangement position of the insulating member 80, and the first and second conductive cooling parts 30 and 40 are electrically insulated from each other.

### (1-2) Another Mode 2

A rectifying-element-module cooling unit 200B of another mode 2 according to the second embodiment of the present invention is described. FIG. 11B is a side view of a rectifying-element-module cooling unit of another mode 2 according to the second embodiment of the present invention. The rectifying-element-module cooling unit 200B is different from the rectifying-element-module cooling unit 200 depicted in FIG. 7 in the arrangement position of the cooling promoting part 50. Only the different point is described below. While the first and second conductive cooling parts 30 and 40 are arranged on the arrangement surface 51 of the cooling promoting part 50 in the rectifying-element-module cooling unit 200, only the second conductive cooling part 40 is directly arranged on the arrangement surface 51 of the cooling promoting part 50 not via the insulating member 80 in the rectifying-element-module cooling unit 200B. The substrate 20 and the first conductive cooling part 30 are not arranged on the arrangement surface 51. The first conductive cooling part 30 and the second conductive cooling part 40 are electrically insulated from each other.

### (1-2) Another Mode 3

A rectifying-element-module cooling unit 200C of another mode 3 according to the second embodiment of the present invention is described. FIG. 11C is a side view of a rectifying-element-module cooling unit of another mode 3 according to the second embodiment of the present invention. The rectifying-element-module cooling unit 200C is different from the rectifying-element-module cooling unit 200 depicted in FIG. 7 mainly in that the substrate 20 is arranged in the horizontal direction. Only the different point is described below.

In the rectifying-element-module cooling unit 200C, the first conductive cooling part 30 in a rectangular parallelepiped shape is arranged on the arrangement surface 51 of the cooling promoting part 50. The first conductive cooling part 30 has an upper surface as a horizontal plane and, with the upper surface of the first conductive cooling part 30 and the substrate back surface 22 in surface contact with each other, the substrate 20 is arranged on the first conductive cooling part 30 in the horizontal direction. Also, on the arrangement surface 51, the second conductive cooling part 40 in an L shape in side view is arranged via the insulating member 80. The second conductive cooling part 40 extends upward from a portion in contact with the insulating member 80 and is warped to extend to a position overlapping above the substrate 20. At the position overlapping above the substrate 20, the second conductive cooling part 40 has a fifth contact surface 40c along a vertical plane.

In a standard state of being along the element-body back surface 211a, the first module terminal 212c extends in a perpendicular direction (vertical direction (z direction) in the example of FIG. 11B) with respect to the substrate front surface 21. The element body 211 and the second module terminal 213 are positioned away from the substrate front surface 21 in a perpendicular direction with respect to the first module terminal 212c. Here, the element-body back surface 211a of the element body 211 is along the vertical plane. The element body 211 and the second module terminal 213 are in surface contact with each other via the element-body back surface 211a and one surface of the second module terminal 213. Also, the second module terminal 213 and the second conductive cooling part 40 are in surface contact with each other via the other surface of the second module terminal 213 and the fifth contact surface 40c.

### (2) Modification of Each Part of Rectifying-Element-Module Cooling Unit

### 2-1

In the above-described second embodiment, the first conductive cooling part 30 is configured of, in an L shape in side view, the first portion 31 extending in a plate shape along the substrate back surface 22 and the second portion 32 extending in a plate shape along the arrangement surface 51 of the cooling promoting part 50. However, the first conductive cooling part 30 electrically connects the first module terminal 212c and the secondary-side output (−) line Vout (−) together and is only required to cool heat due to the first current, and its shape is not limited. For example, the first conductive cooling part 30 may have a rectangular parallelepiped shape in contact with the substrate back surface 22 and the arrangement surface 51. Also, while the second conductive cooling part 40 has a rectangular parallelepiped shape, this is not meant to be limited and, for example, the shape may be an L shape in side view.

### 2-2

In the above-described second embodiment, the first portion 31 of the first conductive cooling part 30 extending along the substrate back surface 22 is positioned at a portion corresponding to the tip of the first module terminal 212c. However, in a range in which it is possible to suppress an adverse effect such as destruction of the rectifying element by heat generation due to the first current, the portion corresponding to the tip of the first module terminal 212c and the first portion 31 may be separated to some extent. For example, the first attachment portion 25 and the first portion 31 may be separated to some extent in the z direction. In this case, a wire for electrically connecting a separate portion between the first attachment portion 25 and the first portion 31 is formed on the substrate front surface 21 or the substrate back surface 22. The wire is preferably short to suppress heat of the substrate 20 due to the first current passing therethrough.

### 2-3

In the above-described second embodiment, the second conductive cooling part 40 is arranged in contact with the substrate front surface 21. However, the second conductive cooling part 40 may electrically connect the second module terminal 213 and the secondary-side winding 2c-2d together, and is only required to cool heat due to the second current and may not be in contact with the substrate 20.

### 2-4

In the above-described second embodiment, the rectifying element module 210 is in a three-pin mode including the gate pin 212a, the unused pin 212b, and the first module terminal 212c. However, the number of pins of the rectifying element module 210 is not limited. Also, in the above-described second embodiment, the unused pin 212b is configured to be shorter than the gate pin 212a and the first module terminal 212c. However, the unused pin 212b may also be configured to be long. Since the unused pin 212b is not used, it is not electrically connected to the substrate 20 and other components, although it is inserted into the pin hole in the substrate 20.

### 4. Other Examples of Power Conversion Device Including Synchronous Rectifier Circuit

In each of the above-described embodiments, the power conversion device including the synchronous rectifier circuit depicted in FIG. 3 is taken, by way of example. However, the power conversion device is not limited to this and, for example, may be any of power conversion devices described below.

### (1) Synchronous Rectifier Circuit with Another Structure 1

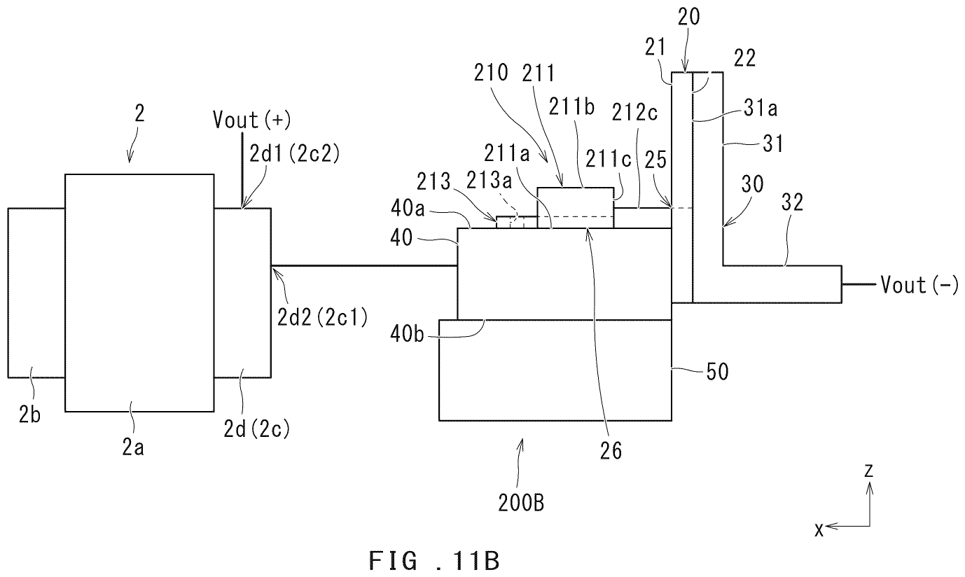

A power conversion device 1A having a synchronous rectifier circuit of another structure 1 is described. FIG. 12 is a circuitry view of a power conversion device having a synchronous rectifier circuit with another structure 1. The power conversion device 1A depicted in FIG. 12 is of a center-tapped type, and includes the transformer 2, the primary-side circuit 3, and a secondary-side circuit 4A. The power conversion device 1A is different from the power conversion device 1 of FIG. 3 mainly in that the first part winding start end 2c1 and the second part winding finish end 2d2 are connected to the secondary-side output (+) line Vout (+) via the secondary-circuit 4A and the connecting portion between the first part winding finish end 2c2 and the second part winding start end 2d1 is connected to the secondary-side output (−) line Vout (−). The other structures of the power conversion device 1Ai are similar to those of the power conversion device 1. Focusing on these different points, description is further made below.

The first drain terminal D1 and the second drain terminal D2 are connected to the secondary-side output (+) line Vout (+) (in the structure of FIG. 12, one example of the second external member). The first source terminal S1 and the second source terminal S2 are connected to the secondary-side winding 2c-2d (in the structure of FIG. 12, one example of the first external member). Specifically, the first source terminal S1 is connected to the first part winding start end 2c1, and the second source terminal S2 is connected to the second part winding finish end 2d2. To a third gate terminal G3 and a fourth gate terminal G4, the first gate signal g1 and the second gate signal g2, respectively, are inputted.

As with each of the above-described embodiments, the first and second transistors Q1 and Q2 are included in different rectifying element modules 10 or rectifying element modules 210.

When the first transistor Q1 is turned ON and the second transistor Q2 is turned OFF, a signal from the secondary-side output (−) line Vout (−) is supplied to the first part winding finish end 2c2 of the first part winding 2c. Output voltage induced at the first part winding 2c flows as a first current from the first part winding start end 2cl via the first current path 60 including the first penetrating current path 61 and the first conductive cooling path 62 to the first source terminal S1. A second current flows from the first drain terminal D1 via the second current path 70 including the second penetrating current path 71 and the second conductive cooling path 72, and output voltage is outputted from the secondary-side output (+) line Vout (+.

On the other hand, when the second transistor Q2 is turned ON and the first transistor Q1 is turned OFF, a signal from the secondary-side output (−) line Vout (−) is supplied to the second part winding start end 2d1 of the second part winding 2d. Output voltage induced at the second part winding 2d flows as a first current from the second part winding finish end 2d2 via the first current path 60 including the first penetrating current path 61 and the first conductive cooling path 62 to the f second source terminal S2. A second current flows from the second drain terminal D2 via the second current path 70 including the second penetrating current path 71 and the second conductive cooling path 72, and output voltage is outputted from the secondary-side output (+) line Vout (+).

### (2) Synchronous Rectifier Circuit with Another Structure 2

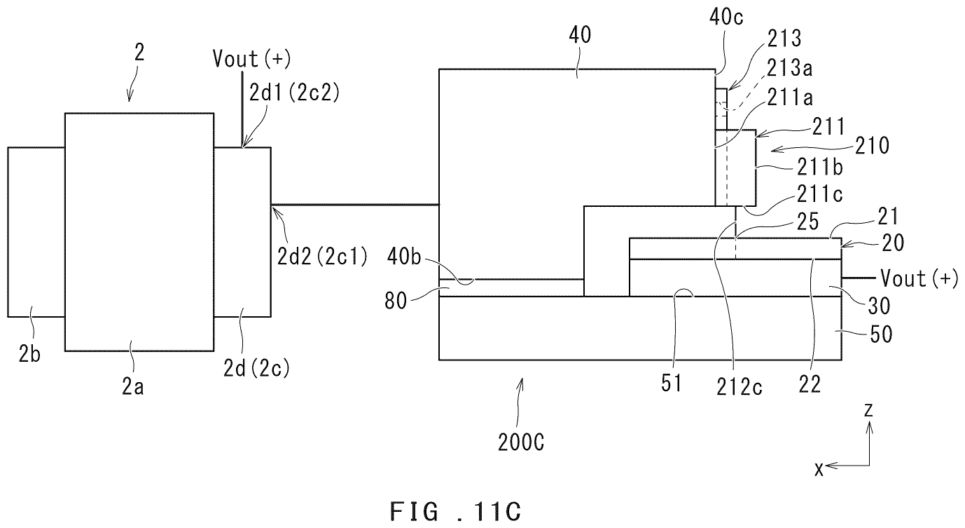

A power conversion device 1B having a synchronous rectifier circuit of another structure 2 is described. FIG. 13 is a circuitry view of a power conversion device having a synchronous rectifier circuit with another structure 2. The power conversion device 1B depicted in FIG. 13 is of a full-bridge type, and includes the transformer 2, the primary-side circuit 3, and a secondary-side circuit 4B. The power conversion device 1B is different from the power conversion device 1 of FIG. 3 mainly in a secondary-side winding 2e provided in place of the secondary-side winding 2c-2d and the structure of the secondary-side circuit 4B. The other structures of the power conversion device 1B are similar to those of the power conversion device 1. Focusing on these different points, description is further made below.

The secondary-side circuit 4B has first to fourth transistors Q1 to Q4. The first and fourth transistors Q1 and Q4 and the second and third transistors Q2 and Q3 are alternately turned ON and OFF. The first and second transistors Q1 and Q2 are connected in series and have the first source terminal S1 and the second drain terminal D2 connected thereto. Also, the third and fourth transistors Q3 and Q4 are connected in series and have a third source terminal S3 and a fourth drain terminal D4 connected thereto.

The first drain terminal D1 is connected to the secondary-side output (+) line Vout (+) (in the structure of FIG. 13, one example of the second external member). The first source terminal S1 is connected to the secondary-side winding 2e (in the structure of FIG. 13, one example of the first external member). Specifically, the first source terminal S1 is connected to a secondary-side winding start end 2e1. To the first gate terminal G1, the first gate signal g1 is inputted.

The second drain terminal D2 is connected to the secondary-side winding 2e (in the structure of FIG. 13, one example of the second external member). Specifically, the second drain terminal D2 is connected to the secondary-side winding start end 2e1. The second source terminal S2 is connected to the secondary-side output (−) line Vout (−) (in the structure of FIG. 13, one example of the first external member). To the second gate terminal G2, the second gate signal g2 is inputted.

The third drain terminal D3 is connected to the secondary-side output (+) line Vout (+) (in the structure of FIG. 13, one example of the second external member). The third source terminal S3 is connected to the secondary-side winding 2e (in the structure of FIG. 13, one example of the first external member). Specifically, the third source terminal S3 is connected to a secondary-side winding finish end 2e2. To the third gate terminal. G3, the second gate signal g2 is inputted.

The fourth drain terminal D4 is connected to the secondary-side winding 2e (in the structure of FIG. 13, one example of the second external member). Specifically, the fourth drain terminal D4 is connected to the secondary-side winding finish end 2e2. The fourth source terminal S4 is connected to the secondary-side output (−) line Vout (−) (in the structure of FIG. 13, one example of the first external member). To the fourth gate terminal G4, the first gate signal g1 is inputted.

As with each of the above-described embodiments, the first to fourth transistors Q1 to Q4 are included in different rectifying element modules 10 or rectifying element modules 210.

When the first and fourth transistors Q1 and Q4 are turned ON and the second and third transistors Q2 and Q3 are turned OFF, a signal from the secondary-side output (−) line Vout (−) is transferred as a first current via the first current path 60 including the first penetrating current path 61 and the first conductive cooling path 62 to the fourth source terminal S4, and the current flows from the fourth source terminal S4 to the fourth drain terminal D4. A second current flows from the fourth drain terminal D4 via the second current path 70 including the second penetrating current path 71 and the second conductive cooling path 72 to the secondary-side winding finish end 2e2 of the secondary-side winding 2e. Output voltage induced at the secondary-side winding 2e is transferred as a first current from the secondary-side winding start end 2e1 via the first current path 60 including the first penetrating current path 61 and the first conductive cooling path 62 to the first source terminal S1, and the current flows from the first source terminal S1 to the first drain terminal D1. A second current flows from the first drain terminal D1 via the second current path 70 including the second penetrating current path 71 and the second conductive cooling path 72, and is outputted from the secondary-side output (+) line Vout (+) as output voltage.

On the other hand, when the second and third transistors Q2 and Q3 are turned ON and the first and fourth transistors Q1 and Q4 are turned OFF, a signal from the secondary-side output (−) line Vout (−) is transferred as a first current via the first current path 60 including the first penetrating current path 61 and the first conductive cooling path 62 to the second source terminal S2, and the current flows from the second source terminal S2 to the second drain terminal D2. A second current flows from the second drain terminal D2 via the second current path 70 including the second penetrating current path 71 and the second conductive cooling path 72 to the secondary-side winding start end 2e1 of the secondary-side winding 2e. Output voltage induced at the secondary-side winding 2e is transferred as a first current from the secondary-side winding finish end 2e2 via the first current path 60 including the first penetrating current path 61 and the first conductive cooling path 62 to the third source terminal S3, and the current flows from the third source terminal S3 to the third drain terminal D3. A second current flows from the third drain terminal D3 via the second current path 70 including the second penetrating current path 71 and the second conductive cooling path 72, and is outputted from the secondary-side output (+) line Vout (+) as output voltage.

### (3) Synchronous Rectifier Circuit with Another Structure 3

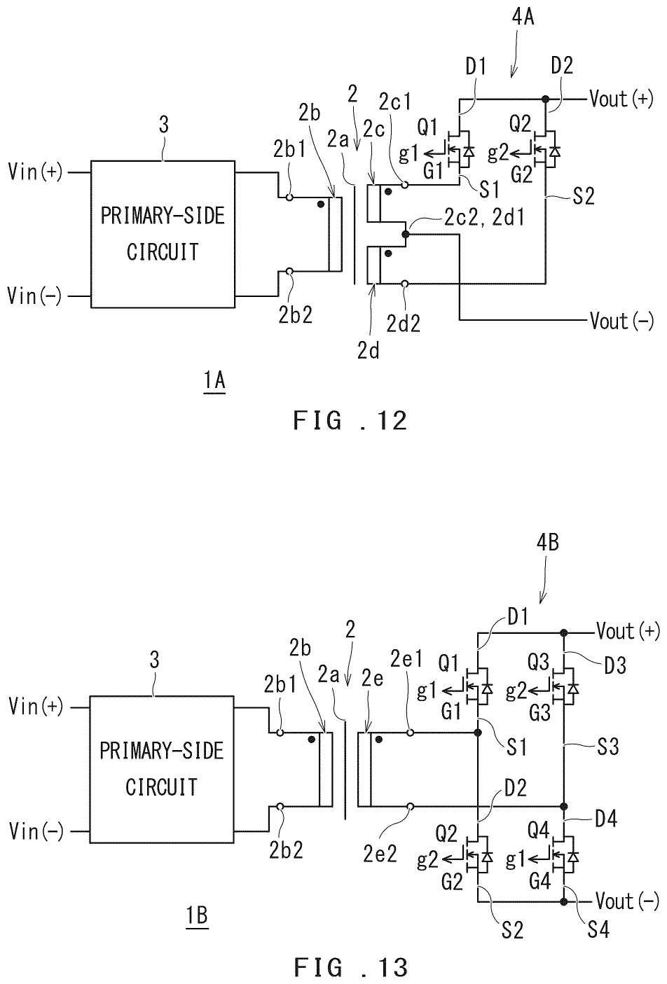

A power conversion device 1C having a synchronous rectifier circuit of another structure 3 is described. FIG. 14 is a circuitry view of a power conversion device having a synchronous rectifier circuit with another structure 3. The power conversion device 1C depicted in FIG. 14 is of a forward type, and includes the transformer 2, the primary-side circuit 3, and a secondary-side circuit 4C. The power conversion device 1C is different mainly in the secondary-side winding 2e provided in place of the secondary-side windings 2c and 2d and a connection between the secondary-side winding 2e and the first and second transistors Q1 and Q2. The other structures of the power conversion device 1C are similar to those of the power conversion device 1. Focusing on these different points, description is further made below.

The first drain terminal D1 is connected to the secondary-side output (+) line Vout (+) (in the structure of FIG. 14, one example of the second external member). The first source terminal S1 is connected to the secondary-side winding 2e (in the structure of FIG. 14, one example of the first external member). Specifically, the first source terminal S1 is connected to the secondary-side winding start end 2e1. To the first gate terminal G1, the first gate signal g1 is inputted.

The second drain terminal D2 is connected to the secondary-side output (+) line Vout (+) (in the structure of FIG. 14, one example of the second external member). The second source terminal S2 is connected to the secondary-side winding 2e (in the structure of FIG. 14, one example of the first external member) and the secondary-side output (−) line Vout (−) (in the structure of FIG. 14, one example of the first external member). Specifically, the second source terminal S2 is connected to the secondary-side winding finish end 2e2 and the secondary-side output (−) line Vout (−). To the second gate terminal G2, the second gate signal g2 is inputted.

As with each of the above-described embodiments, the first and second transistors Q1 and Q2 are included in different rectifying element modules 10 or rectifying element modules 210.

When the first transistor Q1 is turned ON and the second transistor Q2 is turned OFF, a signal from the secondary-side output (−) line Vout (−) is supplied to the secondary-side winding finish end 2e2 of the secondary-side winding 2e. Output voltage induced at the secondary-side winding 2e is transferred as a first current from the secondary-side winding start end 2e1 via the first current path 60 including the first penetrating current path 61 and the first conductive cooling path 62 to the first source terminal S1, and the current flows from the first source terminal S1 to the first drain terminal D1. A second current flows from the first drain terminal D1 via the second current path 70 including the second penetrating current path 71 and the second conductive cooling path 72, and output voltage is outputted from the secondary-side output (+) line Vout (+).

On the other hand, when the first transistor Q2 is turned ON and the second transistor Q1 is turned OFF, the secondary-side output (−) line Vout (−) and the secondary-side output (+) line Vout (+) conduct via the second transistor Q2.

### (4) Synchronous Rectifier Circuit with Another Structure 4

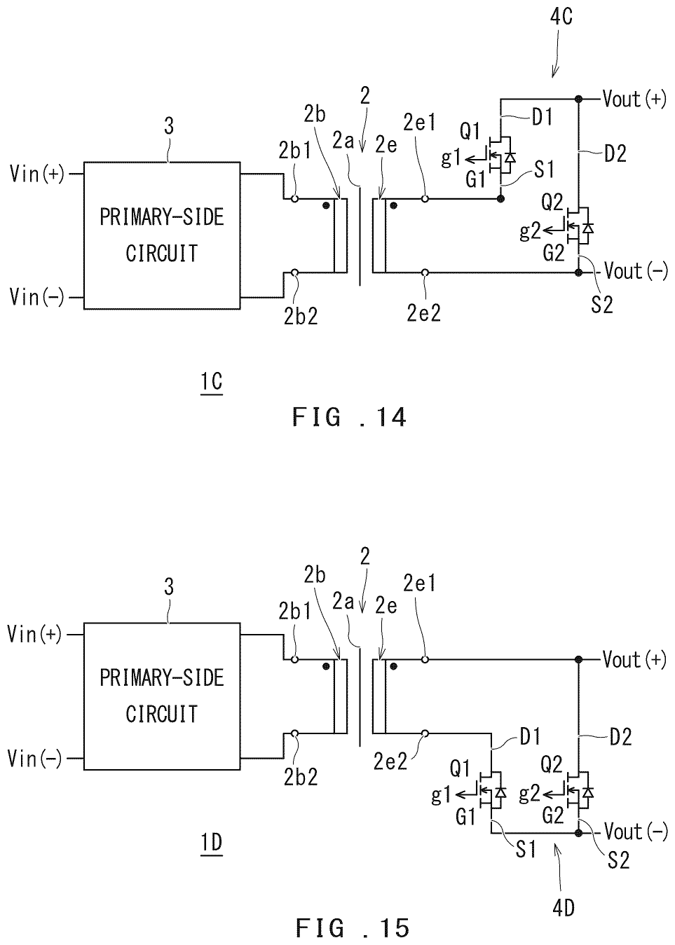

A power conversion device 1D having a synchronous rectifier circuit of another structure 4 is described. FIG. 15 is a circuitry view of a power conversion device having a synchronous rectifier circuit with another structure 4. The power conversion device 1D depicted in FIG. 15 is of a forward type, and includes the transformer 2, the primary-side circuit 3, and a secondary-side circuit 4D. The power conversion device 1D is different from the power conversion device 1C of FIG. 14 mainly in a connection between the secondary-side winding 2e and the first and second transistors Q1 and Q2. The other structures of the power conversion device 1D are similar to those of the power conversion device 1C. Focusing on these different points, description is further made below.

The first drain terminal D1 is connected to the secondary-side winding 2e (in the structure of FIG. 15, one example of the second external member). Specifically, the first drain terminal D1 is connected to the secondary-side winding finish end 2e2. The first source terminal S1 is connected to the secondary-side output (−) line Vout (−) (in the structure of FIG. 15, one example of the first external member). To the first gate terminal G1, the first gate signal g1 is inputted.

The second drain terminal D2 is connected to the secondary-side output (+) line Vout (+) (in the structure of FIG. 15, one example of the second external member) and the secondary-side winding 2e (in the structure of FIG. 15, one example of the second external member). Specifically, the first drain terminal D2 is connected to the secondary-side output (+) line Vout (+) and the secondary-side winding start end 2e1. The second source terminal S2 is connected to the secondary-side output (−) line Vout (−) (in the structure of FIG. 15, one example of the first external member). To the second gate terminal G2, the second gate signal g2 is inputted.

As with each of the above-described embodiments, the first and second transistors Q1 and Q2 are included in different rectifying element modules 10 or rectifying element modules 210.

When the first transistor Q1 is turned ON and the second transistor Q2 is turned OFF, a signal from the secondary-side output (−) line Vout (−) is transferred as a first current via the first current path 60 including the first penetrating current path 61 and the first conductive cooling path 62 to the first source terminal S41 and the current flows from the first source terminal S1 to the first drain terminal D1. A second current flows from the first drain terminal D1 via the second current path 70 including the second penetrating current path 71 and the second conductive cooling path 72 and is supplied to the secondary-side winding finish end 2e2 of the secondary-side winding 2e. Output voltage induced at the secondary-side winding 2e is outputted from the secondary-side winding start end 2e1 to the secondary-side output (+) line Vout (+).

On the other hand, when the second transistor Q2 is turned ON and the first transistor Q1 is turned OFF, the secondary-side output (−) line Vout (−) and the secondary-side output (+) line Vout (+) conduct via the second transistor Q2.

### (5) Rectifier Circuit

In each of the above-described embodiments, the secondary-side circuit 4 includes a synchronous rectifier circuit including the first and second transistors Q1 and Q2. However, the secondary-side circuit 4 is only required to be able to rectify the output voltage induced at the secondary-side winding 2c-2d, and may include not a synchronous rectifier circuit but a rectifier circuit. The rectifier circuit includes, for example, as a rectifying element, a diode (one example of a rectifying element) in place of the first and second transistors Q1 and Q2. The diode has an anode (one example of the first element terminal) and a cathode (one example of the second element terminal), a current flows from the anode to the cathode in a forward direction, and a current does not flow from the cathode to the anode in a backward direction. Thus, the diode performs switching operation based on a difference in voltage applied to the anode and the cathode. Output voltage rectified by this rectifying operation of the diode is obtained as an output of the rectifier circuit.

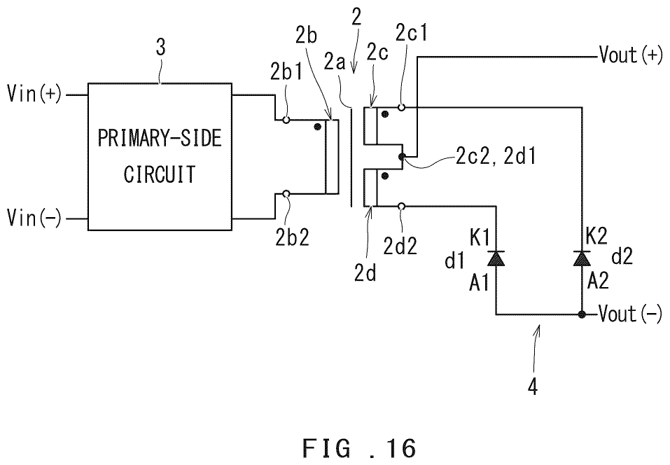

Specifically, for example, a rectifier circuit depicted in FIG. 16 can be taken. FIG. 16 is a circuitry view of a power conversion device having a rectifier circuit.

In FIG. 16, it is assumed that a first diode d1 (one example of the rectifying element) in place of the first transistor Q1 and a second diode d2 (one example of the rectifying element) in place of the second transistor Q2 are provided as diodes. The first diode d1 has a first anode A1 (corresponding to the first source terminal S1 of FIG. 3) and a first cathode K1 (corresponding to the first drain terminal D1 of FIG. 3). The second diode d2 has a second anode A2 (corresponding to the second source terminal S2 of FIG. 3) and a second cathode K2 (corresponding to the second drain terminal D2 of FIG. 3). The first and second anodes A1 and A2 are both connected to the secondary-side output (−) line Vout (−). The first and second cathodes K1 and K2 are connected to the secondary-side winding 2c-2d. Specifically, the first cathode K1 is connected to the second part winding finish end 2d2, and the second cathode K2 is connected to the first part winding start end 2c1. With current alternately flowing through the first and second diodes d1 and d2, the rectified output voltage is outputted from the secondary-side output (+) line Vout (+).

Note that while the embodiments of the present invention are disclosed as described above, the present invention is not limited to these embodiments.

In each of the above-described embodiments, the rectifying element module is the rectifying element module 10 as a surface mount component or the rectifying element module 210 as a discrete component. However, the rectifying element module of the present invention is any including a rectifying element having a rectifying function, and is not limited by the specific structure for achieving this function and the specific details of a form of mounting the module on the substrate.

Also, in the first embodiment, the second module terminal 13 is connected to the second current path 70 via the element-body back surface 11a opposed to the substrate front surface 21, and the first module terminal 12c extends from a surface of the element body 11 other than the element-body back surface 11a along the substrate front surface 21 to be connected to the first current path 60. However, a connection between the second module terminal 13 and the second current path 70 and a connection between the first module terminal 12c and the first current path 60 are not limited to those described above, and can take any mode.

Also, in the second embodiment, the second module terminal 13 is connected to the second current path 70 via the element-body back surface 211a opposed to the substrate front surface 21, and the first module terminal 212c extends from a surface of the element body 211 other than the element-body back surface 211a toward the substrate front surface to be connected to the first current path 60. However, a connection between the second module terminal 213 and the second current path 70 and a connection between the first module terminal 212c and the first current path 60 are not limited to those described above, and can take any mode.

Furthermore, in the second embodiment, the second conductive cooling path 72 passes through the second conductive cooling part 40 not via the substrate 20. However, the second conductive cooling path 72 may pass therethrough via the substrate 20.

That is, it is possible to variously change any mechanism, shape, material, quantity, position, arrangement, or the like of the embodiments described above without deviating from the technical idea and object of the present invention, and those changes are included in the present invention.

1. A rectifying-element-module cooling unit, comprising:
a rectifying element module including an element body in which a rectifying element having a first element terminal and a second element terminal is arranged, a first module terminal electrically connected to the first element terminal, and a second module terminal electrically connected to the second element terminal;
a substrate formed in a plate shape, having a substrate front surface and a substrate back surface, the rectifying element module being arranged on the substrate front surface side;
a first conductive cooling part for electrically connecting a first external member arranged outside the rectifying-element-module cooling unit and the first module terminal together and mainly cooling heat generated by a first current passing through the first element terminal;
a second conductive cooling part for electrically connecting a second external member arranged outside the rectifying-element-module cooling unit and the second module terminal together and mainly cooling heat generated by a second current passing through the second element terminal; and
a cooling promoting part with conductive, promoting for cooling the first conductive cooling part and the second conductive cooling part, having an arrangement surface where the first conductive cooling part and the second conductive cooling part are arranged, and being electrically connected, via the arrangement surface, to one of the first conductive cooling part and the second conductive cooling part and insulatively connected to the other thereof, wherein
part of a first current path of the first current from the first element terminal via the first module terminal and the first conductive cooling part to the first external member is configured of a first penetrating current path penetrating through the substrate from the substrate front surface to the substrate back surface.

2. The rectifying-element-module cooling unit according to claim 1, wherein
part of a second current path of the second current from the second element terminal via the second module terminal and the second conductive cooling part to the second external member is configured of a second penetrating current path penetrating through the substrate from the substrate front surface to the substrate back surface.

3. The rectifying-element-module cooling unit according to claim 2, wherein
the rectifying element module is surface-mounted on the substrate front surface via an element-body back surface,
the second module terminal is connected to the second current path via the element-body back surface opposed to the substrate front surface, and
the first module terminal extends from a surface of the element body other than the element-body back surface along the substrate front surface to be connected to the first current path.

4. The rectifying-element-module cooling unit according to claim 1, wherein
part of a second current path of the second current from the second element terminal via the second module terminal and the second conductive cooling part to the second external member is configured of a second conductive cooling path passing the second conductive cooling part not via the substrate.

5. The rectifying-element-module cooling unit according to claim 4, wherein
the rectifying element module is mounted on the substrate front surface,
the second module terminal is connected to the second current path via the element-body back surface opposed to the second conductive cooling part, and
the first module terminal extends from a surface of the element body other than the element-body back surface toward the substrate front surface to be connected to the first current path.

6. The rectifying-element-module cooling unit according to claim 1, wherein
the first conductive cooling part and the second conductive cooling part are each formed as a bus bar.

7. The rectifying-element-module cooling unit according to claim 1, wherein
the substrate is arranged in a state in which the substrate front surface and the substrate back surface are parallel to the cooling promoting part.

8. The rectifying-element-module cooling unit according to claim 1, wherein
the substrate stands in a state in which the substrate front surface and the substrate back surface are perpendicular to the cooling promoting part.

9. The rectifying-element-module cooling unit according to claim 1, wherein
a first attachment portion where the first module terminal is attached to the substrate is opposed to at least part of the first conductive cooling part via the substrate.

10. The rectifying-element-module cooling unit according to claim 1, wherein
a second attachment portion where the second module terminal is attached to the substrate is opposed to at least part of the second conductive cooling part via the substrate.

11. The rectifying-element-module cooling unit according to claim 1, wherein
the first external member is at least either of a secondary-side winding of a transformer and a secondary-side output line of the transformer, and the second external member is at least either of the secondary-side winding of the transformer and the secondary-side output line of the transformer.

12. The rectifying-element-module cooling unit according to claim 1, wherein
the rectifying element is a transistor, and
each of the first element terminal and the second element terminal is either of a drain terminal and the source terminal of the transistor.

13. The rectifying-element-module cooling unit according to claim 1, wherein
the rectifying element is a diode, and
each of the first element terminal and the second element terminal is either of an anode and a cathode of the diode.

14. The rectifying-element-module cooling unit according to claim 2, wherein
a first attachment portion where the first module terminal is attached to the substrate is opposed to at least part of the first conductive cooling part via the substrate.

15. The rectifying-element-module cooling unit according to claim 2, wherein
a second attachment portion where the second module terminal is attached to the substrate is opposed to at least part of the second conductive cooling part via the substrate.

16. The rectifying-element-module cooling unit according to claim 2, wherein
the first external member is at least either of a secondary-side winding of a transformer and a secondary-side output line of the transformer, and the second external member is at least either of the secondary-side winding of the transformer and the secondary-side output line of the transformer.

17. The rectifying-element-module cooling unit according to claim 2, wherein
the rectifying element is a transistor, and
each of the first element terminal and the second element terminal is either of a drain terminal and the source terminal of the transistor.

18. The rectifying-element-module cooling unit according to claim 2, wherein
the rectifying element is a diode, and
each of the first element terminal and the second element terminal is either of an anode and a cathode of the diode.
